(19) United States
(12) Patent Application Publication
(10) Pub. No.: US 2008/0265959 A1
(43) Pub. Date: Oct. 30, 2008

(54) PLL circuit and frequency setting circuit employing the same

(75) Inventor: Katsuji Kimura, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS COPORATION, Kawasaki (JP)

(21) Appl. No.: 12/081,987

(22) Filed: Apr. 24, 2008

(30) Foreign Application Priority Data
Apr. 26, 2007 (JP) 2007-117319

(51) Int. Cl. H03L 7/06

(52) U.S. Cl. 327/156; 327/158

(57) ABSTRACT

Disclosed is a PLL circuit in which an output signal of a frequency oscillator (VCO or ICO), an oscillation frequency of which is controlled by an electrical signal, is supplied via a high pass filter (HPF) to one of input terminals of a phase detector, the other input terminal of which receives a reference frequency. An output signal of the phase detector is supplied to a loop filter which then outputs a DC component of the signal that controls the frequency oscillator as the electrical signal.

### REFERENCE TO RELATED APPLICATION

This invention is based on and claims the benefit of the priority of Japanese Patent Application No. 2007-117319, filed on Apr. 26, 2007, the disclosure of which is incorporated herein in its entirety by reference thereto.

### FIELD OF THE INVENTION

This invention relates to a PLL circuit and a frequency setting circuit for a filter employing the same. More particularly, this invention relates to a PLL circuit formed on a semiconductor IC and to a frequency setting circuit for a gm-C filter that makes use of the PLL circuit and which is made up of OTAs (operational transconductance amplifiers) and a capacitor.

### BACKGROUND OF THE INVENTION

FIG. 1 shows a conventional PLL circuit. A typical conventional PLL circuit is made up of three functional blocks. These are a voltage-controlled oscillator (VCO) 203, a phase detector (PD) 201 and a loop filter (LP) 202.

The phase detector (PD) 201 detects the phase difference between an output of the voltage-controlled oscillator (VCO) 203 and an input signal to generate a signal proportionate to a phase error. The phase detector (PD) 201 is also referred to as a phase comparator.

An output of the phase detector (PD) 201 contains a DC component and an AC component. The DC component is accumulated, while the AC component is removed by the loop filter (LP) 202.

An output of the loop filter (LP) 202 is close to a DC signal, and is supplied to the voltage-controlled oscillator (VCO) 203. This nearly DC signal causes the oscillation frequency of the VCO 203 to be changed in a direction of decreasing the phase error between an output signal of the VCO 203 and the input signal.

A linear PLL circuit model is shown in FIG. 2.

Referring to FIG. 2, the closed-loop transfer function H(s) of the PLL circuit may be defined, based on a control theory, by the following equation (1):

$$H ( s ) ≡ \frac{{θ}_{o} ( s )}{{θ}_{i} ( s )} = \frac{{K}_{d} {K}_{0} F ( s )}{s + {K}_{d} {K}_{0} F ( s )} \qquad ( 1 )$$

In the above equation, Kd[V/rad] is the gain of a phase detector,

F(s) is a transfer function of a loop filter (LP), and

K0[rad/s-V] is a gain factor of the VCO.

A phase transfer function is further added. The phase error transfer function He(s) is then defined by the following equation (2):

$${H}_{e} ( s ) ≡ \frac{{θ}_{e} ( s )}{{θ}_{i} ( s )} = \frac{s}{s + {K}_{d} {K}_{o} F ( s )} \qquad ( 2 )$$

So far hitherto, in a PLL circuit, making use of this sort of the voltage-controlled oscillator (VCO) or a current-controlled oscillator (ICO), a phase delay of 90° is produced in the voltage-controlled oscillator (VCO) or in the current-controlled oscillator (ICO), and a phase delay is further produced by a loop filter inserted on an output side of the phase detector. Thus, to implement a stabilized PLL circuit, a phase margin within a loop is secured using a lag-lead filter as a loop filter.

Since the PLL loop is a negative feedback circuit, the phase shift in the loop must be within a range of −180° to 180°. The reason is that, if phase shift exceeds this range, the negative feedback is turned into positive feedback such that it is not possible to configure a PLL.

There is possibly no other alternative but to replace the lag-lead filter by a passive filter (FIG. 3A), an active filter (FIG. 3B), or by an active PI (proportionate integrating) filter (FIG. 3C).

However, for actual use, it is desirable to remove an AC component. Thus, in actuality, there are many instances where a capacitor of a capacitance value sufficiently smaller than that used in the lag-lead filter (loop filter) is added between the signal path of a control voltage and the ground.

A transfer function F(s) of a passive lag-lead filter, shown in FIG. 3A, is given by:

$$F ( s ) = \frac{1 + s {τ}_{2}}{1 + s ( {τ}_{1} + {τ}_{2} )} \qquad ( 3 )$$

where τ₁=R₁C and τ₂=R₂C.

A transfer function F(s) of the active lag-lead filter, shown in FIG. 3B, is given by:

$$F ( s ) = {K}_{a} \frac{1 + s {τ}_{2}}{a + s {τ}_{1}} \qquad ( 4 )$$

where τ₁=R₁C₁, τ₂=R₂C₂ and Kₐ=C₁/C₂.

A transfer function F(s) of the active PI filter, shown in FIG. 3C, is given by:

$$F ( s ) = \frac{1 + s {τ}_{2}}{s {τ}_{1}} \qquad ( 5 )$$

where τ₁=R₁C and τ₂=R₂C.

In the case of the passive lag-lead filter, shown in FIG. 3A, H(s) is expressed, from the equations (1) and (3), by:

$$\begin{matrix}H ( s ) = \frac{{K}_{d} {K}_{0} \frac{1 + s {τ}_{2}}{{τ}_{1} + {τ}_{2}}}{{s}^{2} + s \frac{1 + {K}_{d} {K}_{0} {τ}_{2}}{{τ}_{1} + {τ}_{2}} + \frac{{K}_{d} {K}_{0}}{{τ}_{1} + {τ}_{2}}} \\ = \frac{{ω}_{n} ( 2 ξ - \frac{{ω}_{n}}{{K}_{d} {K}_{0} } ) s + {ω}_{n}^{2}}{{s}^{2} + 2 s ξ {ω}_{n} + {ω}_{n}^{2}}\end{matrix} \qquad ( 6 )$$

In the case of the passive lag-lead filter, shown in FIG. 3A, Hₑ(s) is expressed, from the equations (2) and (3), by:

$${H}_{e} ( s ) = \frac{{s}^{2} + \frac{1}{{τ}_{1} + {τ}_{2}} s}{{s}^{2} + s \frac{1 + {K}_{d} {K}_{0} {τ}_{2}}{{τ}_{1} + {τ}_{2}} + \frac{{K}_{d} {K}_{0}}{{τ}_{1} + {τ}_{2}}} = \frac{{s}^{2} + \frac{1}{{τ}_{1} + {τ}_{2}} s}{{s}^{2} + 2 s {ξω}_{n} + {ω}_{n}^{2}} \qquad ( 7 )$$

It should be noticed that ωₙ and ζ denote a natural frequency and a dumping factor, respectively, and are expressed by the equations (8) and (9), respectively:

$${ω}_{n} = \sqrt{\frac{{K}_{d} {K}_{0}}{{τ}_{1} + {τ}_{2}}} \qquad ( 8 )$$

$$ξ = \frac{{ω}_{n}}{2} ( \frac{1}{{K}_{d} {K}_{0}} + {τ}_{2} ) \qquad ( 9 )$$

For the active lag-lead filter, shown in FIG. 3B, H(s) is expressed by:

$$\begin{matrix}H ( s ) = \frac{{K}_{d} {K}_{a} {K}_{0} \frac{1 + s {τ}_{2}}{{τ}_{1} + {τ}_{2}}}{{s}^{2} + s \frac{1 + {K}_{d} {K}_{a} {K}_{0} {τ}_{2}}{{τ}_{1}} + \frac{{K}_{d} {K}_{a} {K}_{0}}{{τ}_{1}}} \\ = \frac{{ω}_{n} ( 2 ξ - \frac{{ω}_{n}}{{K}_{d} {K}_{a} {K}_{0}} ) s + {ω}_{n}^{2}}{{s}^{2} + 2 s {ξω}_{n} + {ω}_{n}^{2}}\end{matrix} \qquad ( 10 )$$

For the active lag-lead filter, shown in FIG. 3B, Hₑ(s) is expressed by:

$$\begin{matrix}{H}_{e} ( s ) = \frac{{s}^{2} + \frac{1}{{τ}_{1} + {τ}_{2}} s}{{s}^{2} + s \frac{1 + {K}_{d} {K}_{a} {K}_{0} {τ}_{2}}{{τ}_{1}} + \frac{{K}_{d} {K}_{a} {K}_{0}}{{τ}_{1}}} \\ = \frac{{s}^{2} + \frac{1}{{τ}_{1} + {τ}_{2}} s}{{s}^{2} + 2 s {ξω}_{n} + {ω}_{n}^{2}}\end{matrix} \qquad ( 11 )$$

where ωₙ and ζ denote a natural frequency and a dumping factor, respectively, and are expressed by the equations (12) and (13), respectively:

$${ω}_{n} = \sqrt{\frac{{K}_{d} {K}_{a} {K}_{0}}{{τ}_{1}}} \qquad ( 12 )$$

$$ξ = \frac{{ω}_{n}}{2} ( \frac{1}{{K}_{d} {K}_{a} {K}_{0}} + {τ}_{2} ) \qquad ( 13 )$$

For the active PI filter, shown in FIG. 3C, H(s) is expressed by:

$$H ( s ) = \frac{{K}_{d} {K}_{0} \frac{1 + s {τ}_{2}}{{τ}_{1}}}{{s}^{2} + s \frac{1 + {K}_{d} {K}_{0} {τ}_{2}}{{τ}_{1}} + \frac{{K}_{d} {K}_{0}}{{τ}_{1}}} = \frac{( 2 ξ {ω}_{n} - \frac{1}{{τ}_{1}} ) s + {ω}_{n}^{2}}{{s}^{2} + 2 s ξ {ω}_{n} + {ω}_{n}^{2}} \qquad ( 14 )$$

For the active PI filter, shown in FIG. 3C, Hₑ(S) is expressed by:

$${H}_{e} ( s ) = \frac{{s}^{2} + \frac{1}{{τ}_{1}} s}{{s}^{2} + s \frac{1 + {K}_{d} {K}_{0} {τ}_{2}}{{τ}_{1}} + \frac{{K}_{d} {K}_{0}}{{τ}_{1}}} = \frac{{s}^{2} + \frac{1}{{τ}_{1}} s}{{s}^{2} + 2 s ξ {ω}_{n} + {ω}_{n}^{2}} \qquad ( 15 )$$

where ωₙ and ζ denote the natural frequency and a dumping factor, respectively, and are expressed by the following equations (16) and (17), respectively:

$${ω}_{n} = \sqrt{\frac{{K}_{d} {K}_{0}}{{τ}_{1}}} \qquad ( 16 )$$

$$ξ = \frac{{ω}_{n}}{2} ( \frac{1}{{K}_{d} {K}_{0}} + {τ}_{2} ) \qquad ( 17 )$$

where ωₙ and ζ are crucial parameters that determine the characteristic of the PLL circuit.

If K_{d}K₀>>ωₙ or K_{d}KₐK₀>>ωₙ, the PLL system is said to be a high gain loop.

The most commonly used PLL is a high-gain loop to improve a tracking characteristic. With the high-gain loop, the equations (6) and (10) may be expressed by the following approximation (18). If the time constant is of a large value, such that 1<<τ1, the equation (14) may also be expressed by the same approximation:

$$H ( s ) \approx \frac{2 {ξω}_{n} s + {ω}_{n}^{2}}{{s}^{2} + 2 s ξ {ω}_{n} + {ω}_{n}^{2}} \qquad ( 18 )$$

The analysis of the related arts will be given by the present invention. FIG. 4 shows amplitude characteristics of the closed-loop transfer function shown by the equation (18) which is an approximation for the high gain loop of the equations (14), (6) and (10). The characteristics (a), (b), (c), (d) and (e) represent the amplitude characteristics of the closed-loop transfer function H(s) with the values of the dumping factor ζ of 0.1, 0.25, 0.5, 0.7071 and 1, respectively. The horizontal axis and the vertical axis represent the normalized frequency ω/ωₙ and the amplitude, respectively.

Even though the dumping factor ζ is changed from 0.1 to 1, the amplitude values which have undergone the overshooting all become equal to 1 for ω/ωₙ=√21, such that, for ω/ωₙ>√2, the amplitude value is smaller than 1.

However, even with the high-gain loop, it may not be necessary to approximate the phase error transfer function Hₑ(s), shown by the equation (7), (11) or (15), by

$${H}_{e} ( s ) \approx \frac{{s}^{2}}{{s}^{2} + 2 s ξ {ω}_{n} + {ω}_{n}^{2}} \qquad ( 19 )$$

for any of the passive lag-lead filter, active lag-lead filter or the active PI filter.

In the denominators of the phase error transfer function Hₑ(s), shown by the equations (7), (11) and (15), there are contained terms of other than the term s².

In case these terms of s are disregarded, the phase error transfer function Hₑ(s), shown by the equation (7), (11) or (15), is the approximation (19).

In case of large values of τ₁ and τ₁+τ₂ (1<<τ₁ or 1<<τ₁+τ₂), the terms of s may be disregarded and the above phase error transfer function may be expressed by the approximation (19). If however the values of τ₁ and τ₁+τ₂ are small, the result is merely deviated from the approximation (19).

FIG. 5 shows, for reference sake, the amplitude characteristics of the approximation (19) to be used in place of the phase error transfer function Hₑ(s).

Since the maximum number of orders of s of the denominator of the transfer function is 2, the transfer function is known as a second-order loop.

Also, in a well-known manner, the amplitude characteristics |H(jω)| of the loop transfer function H(jω), shown by the equation (18), are second-order LPF (low pass filter) characteristics, while the amplitude characteristics |Hₑ(jω)| of the phase error transfer function Hₑ(jω), shown by the equation (7), (11) or (15), or the amplitude characteristics |Hₑ(jω)| of the phase error transfer function Hₑ(jω), shown by the equation (19), are second-order HPF (high pass filter) characteristics.

Hence, the transfer characteristics H(s) has a −3 dB cut-off frequency ω_{-3 dB}, where −3 dB represents a closed loop band of the PLL circuit.

If, in a high gain loop, the amplitude characteristic |H(jω)| is set so that

$$\vert H ( jω ) \vert = \frac{1}{\sqrt{2}}$$

and the equation is solved for ω and ω_{-3 dB} may be found by

$$\begin{matrix}{ω}_{- 3 dB} = {ω}_{n} \sqrt{2 {ξ}^{2} + 1 + \sqrt{1 + {( 2 {ξ}^{2} + 1 )}^{2}}} \\ = {ω}_{n} \sqrt{2 {ξ}^{2} + 1 + \sqrt{4 {ξ}^{4} + 4 {ξ}^{2} + 2}}\end{matrix} \qquad ( 20 )$$

A PLL circuit, making use of a conventional VCF (voltage-controlled filter), is now described.

The present inventor once had a chance to view a textbook stating the operating principle of the PLL circuit that makes use of a VCF. However, the circuit does not operate in the manner as described.

The PLL circuit that makes use of a VCF is now described in detail in light of the actual circuit operation. The following is the result of analyses by the present inventor.

The conventional PLL circuit, making use of the VCF, is shown in FIG. 6. In actuality, in a linear LPF (phase shifter) 204, used as a phase shifter, the frequency characteristic, specifically a cut-off frequency, is varied by a control voltage. Thus, as with the VCO circuit, shown in FIG. 1, a linear model of a PLL circuit, employing the VCF, is as shown in FIG. 7.

Hence, the situation is similar to that shown in FIG. 2. That is, the closed-loop transfer function of the PLL circuit may be defined, based on the control theory, by the following equation (21):

$$H ( s ) ≡ \frac{{θ}_{0} ( s )}{{θ}_{i} ( s )} = \frac{{K}_{d} \frac{{K}_{1}}{s + {ω}_{0}} F ( s )}{1 + {K}_{d} \frac{{K}_{1}}{s + {ω}_{0}} F ( s )} = \frac{{K}_{d} {K}_{1} F ( s )}{s + {ω}_{0} + {K}_{d} {K}_{1} F ( s )} \qquad ( 21 )$$

where, Kd[V/rad] is the gain of a phase detector,

F(s) is a transfer function of a loop filter (LP), and

K₀[rad/s-V] is a gain factor of the VCO, with the transfer function of the first-order LPF 204 being set to K₀(s+ω₀).

A phase transfer function is further added and hence the phase error transfer function is defined by the following equation (22):

$${H}_{e} ( s ) ≡ \frac{{θ}_{e} ( s )}{{θ}_{1} ( s )} = \frac{1}{1 + {K}_{d} \frac{{K}_{1}}{s + {ω}_{0}} F ( s )} = \frac{s + {ω}_{0}}{s + {ω}_{0} + {K}_{d} {K}_{1} F ( s )} . \qquad ( 22 )$$

Heretofore, in a PLL circuit, making use of this sort of the voltage-controlled first-order low-pass filter (VCF) or a current-controlled first-order low-pass filter (ICF), a phase delay of 90° is produced at the voltage-controlled first-order low-pass filter (VCF) or the current-controlled first-order low-pass filter (ICF). Additionally, a phase delay is caused at the loop filter (LP) inserted on an output of the phase detector (PD). Thus, a lag-lead filter is used as the loop filter to provide for the phase margin within the loop to implement a stabilized PLL circuit.

Since the PLL loop is a negative feedback circuit, the phase shift within the loop must be within a range of −180° to 180°. If the phase shift exceeds this range, the negative feedback is changed to the positive feedback, and hence the PLL circuit cannot be configured.

Or, there is no other alternative but to change the type of the lag-lead filter from a passive type (FIG. 3A) to an active type (FIG. 3B) or to an active PI type (FIG. 3C).

In actuality, there are many instances in which, in an attempt to remove the AC component, a capacitor of a capacitance value sufficiently smaller than that of a capacitor used in the lag-lead filter is added between the signal path of the control voltage and the ground.

On the other hand, there is necessarily produced a phase delay of 0° to 90° at the first-order low pass filter. It is therefore necessary to set the PLL loop so that the loop will be locked with the phase delay of 0° to 90°.

A transfer function F(s) of a passive lag-lead filter, shown in FIG. 3A, is given by:

$$F ( s ) = \frac{1 + s {τ}_{2}}{1 + s ( {τ}_{1} + {τ}_{2} )} \qquad ( 23 )$$

where τ₁=R₁C and τ₂=R₂C.

A transfer function F(s) of the active lag-lead filter, shown in FIG. 3B, is given by:

$$F ( s ) = {K}_{d} \frac{1 + s {τ}_{2}}{1 + s {τ}_{1}} \qquad ( 24 )$$

where τ₁=R₁C₁, τ₂=R₂C₂ and Kₐ=C₁/C₂.

A transfer function F(s) of the active PI filter, shown in FIG. 3C, is given by:

$$F ( s ) = \frac{1 + s {τ}_{2}}{s {τ}_{1}} \qquad ( 25 )$$

where τ₁=R₁C and τ₂=R₂C.

In the case of the passive lag-lead filter, shown in FIG. 3A, the closed-loop transfer function H(s) is expressed by:

$$\begin{matrix}H ( s ) = \frac{\frac{{K}_{d} {K}_{1} {τ}_{2}}{{τ}_{1} + {τ}_{2}} s + \frac{{K}_{d} {K}_{1}}{{τ}_{1} + {τ}_{2}}}{{s}^{2} + ( {ω}_{0} + \frac{1 + {K}_{d} {K}_{1} {τ}_{2}}{{τ}_{1} + {τ}_{2}} ) s + \frac{{K}_{d} {K}_{1} + {ω}_{0}}{{τ}_{1} + {τ}_{2}}} \\ = \frac{( 2 ξ {ω}_{n} - {ω}_{0} - \frac{1}{{τ}_{1} + {τ}_{2}} ) s + {ω}_{n}^{2} - \frac{{ω}_{0}}{{τ}_{1} + {τ}_{2}}}{{s}^{2} + 2 s {ξω}_{n} + {ω}_{n}^{2}}\end{matrix} \qquad ( 26 )$$

In the case of the passive lag-lead filter, shown in FIG. 3A, the phase error transfer function Hₑ(s) is expressed by:

$$\begin{matrix}{H}_{e} ( s ) = \frac{{s}^{2} + ( {ω}_{0} + \frac{1}{{τ}_{1} + {τ}_{2}} ) s}{{s}^{2} + ( {ω}_{0} + \frac{1 + {K}_{d} {K}_{1} {τ}_{2}}{{τ}_{1} + {τ}_{2}} ) s + \frac{{K}_{d} {K}_{1} + {ω}_{0}}{{τ}_{1} + {τ}_{2}}} \\ = \frac{{s}^{2} + ( {ω}_{0} + \frac{1}{{τ}_{1} + {τ}_{2}} ) s}{{s}^{2} + 2 s {ξω}_{n} + {ω}_{n}^{2}}\end{matrix} \qquad ( 27 )$$

It should be noticed that ωₙ and ζ denote a natural frequency and a dumping factor, respectively, and are expressed by the equations (28) and (29), respectively:

$$\begin{matrix}{ω}_{n} = \sqrt{\frac{{K}_{d} {K}_{1} + {ω}_{0}}{{τ}_{1} + {τ}_{2}}} & ( 28 ) \\ ξ = \frac{{ω}_{0}}{2 {ω}_{n}} + \frac{{ω}_{n}}{2} ( \frac{1 + {K}_{d} {K}_{1} {τ}_{2}}{{τ}_{1} + {τ}_{2}} ) & ( 29 )\end{matrix}$$

For the active lag-lead filter, shown in FIG. 3B, the closed-loop transfer function H(s) is expressed by:

$$\begin{matrix}H ( s ) = \frac{\frac{{K}_{d} {K}_{1} {K}_{0} {τ}_{2}}{{τ}_{1}} s + \frac{{K}_{d} {K}_{1} {K}_{0}}{{τ}_{1}}}{{s}^{2} + s \frac{1 + {ω}_{0} + {K}_{d} {K}_{1} {K}_{0} {τ}_{2}}{{τ}_{1}} + \frac{{K}_{d} {K}_{1} {K}_{0} + {ω}_{0}}{{τ}_{1}}} \\ = \frac{( 2 {ξω}_{n} - \frac{{ω}_{0}}{{τ}_{1}} ) s + {ω}_{n}^{2} - \frac{{ω}_{0}}{{τ}_{1}}}{{s}^{2} + 2 s {ξω}_{n} + {ω}_{n}^{2}}\end{matrix} \qquad ( 30 )$$

For an active lag-lead filter, shown in FIG. 3B, the phase error transfer function Hₑ(s) is expressed by:

$$\begin{matrix}{H}_{e} ( s ) = \frac{{s}^{3} + \frac{1 + {ω}_{0}}{{τ}_{1}} s}{{s}^{2} + s \frac{1 + {ω}_{0} + {K}_{d} {K}_{1} {K}_{0} {τ}_{2}}{{τ}_{1}} + \frac{{K}_{d} {K}_{1} {K}_{0} + {ω}_{0}}{{τ}_{1}}} \\ = \frac{{s}^{3} + \frac{1 + {ω}_{0}}{{τ}_{1}} s}{{s}^{2} + 2 s {ξω}_{n} + {ω}_{n}^{2}}\end{matrix} \qquad ( 31 )$$

where ωₙ and ζ denote a natural frequency and a dumping factor, respectively, and are expressed by the equations (32) and (33), respectively:

$$\begin{matrix}{ω}_{n} = \sqrt{\frac{{K}_{d} {K}_{1} {K}_{0} + {ω}_{0}}{{τ}_{1}}} & ( 32 ) \\ ξ = \frac{1 + {ω}_{0}}{2 {τ}_{1} {ω}_{n}} + \frac{{ω}_{n}}{2} ( {τ}_{2} - \frac{{τ}_{2} {ω}_{0}}{{τ}_{1} {ω}_{n}} ) & ( 33 )\end{matrix}$$

For the active PI filter, shown in FIG. 3C, the closed-loop transfer function H(s) is expressed by:

$$\begin{matrix}H ( s ) = \frac{\frac{{K}_{d} {K}_{1} {τ}_{2}}{{τ}_{1}} s + \frac{{K}_{d} {K}_{1}}{{τ}_{1}}}{{s}^{2} + ( {ω}_{0} + \frac{{K}_{d} {K}_{1} {τ}_{2}}{{τ}_{1}} ) s + \frac{{K}_{d} {K}_{1}}{{τ}_{1}}} \\ = \frac{( 2 {ξω}_{n} - {ω}_{0} ) s + {ω}_{n}^{2}}{{s}^{2} + 2 s {ξω}_{n} + {ω}_{n}^{2}}\end{matrix} \qquad ( 34 )$$

For the active PI filter, shown in FIG. 3C, the phase error transfer function Hₑ(s) is expressed by:

$$\begin{matrix}{H}_{e} ( s ) = \frac{{s}^{2} + {ω}_{0} s}{{s}^{2} + ( {ω}_{0} + \frac{{K}_{d} {K}_{1} {τ}_{2}}{{τ}_{1}} ) s + \frac{{K}_{d} {K}_{1}}{{τ}_{1}}} \\ = \frac{{s}^{2} + {ω}_{0} s}{{s}^{2} + 2 s {ξω}_{n} + {ω}_{n}^{2}}\end{matrix} \qquad ( 35 )$$

where ωₙ and ζ denote a natural frequency and a dumping factor, respectively, and are expressed by the following equations (36) and (37), respectively:

$$\begin{matrix}{ω}_{n} = \sqrt{\frac{{K}_{d} {K}_{1}}{{τ}_{1}}} & ( 36 ) \\ ξ = \frac{{ω}_{0}}{2 {ω}_{n}} + \frac{{ω}_{n} {τ}_{2}}{2} & ( 37 )\end{matrix}$$

It should be noticed that ωₙ and ζ are crucial parameters that determine the characteristics of the PLL circuit.

If K_{d}K₀>>ωₙ or K_{d}KₐKₒ>>ωₙ, the PLL system is said to be a high gain loop.

The most commonly used PLL is a high-gain loop to improve tracking characteristic.

Whether the PLL has a high gain loop or a low gain loop, ωₙ>>ω₀ and the time constant is of a large value, such that 1<<τ₁ and 1<<τ₁+τ₂. Hence, the equations (26), (30) and (34) may be expressed by the following approximation (38):

$$H ( s ) \approx \frac{2 s {ξω}_{n} + {ω}_{n}^{2}}{{s}^{2} + 2 s {ξω}_{n} + {ω}_{n}^{2}} \qquad ( 38 )$$

FIG. 8 shows amplitude characteristics of closed loop transfer functions shown by the approximation (38) which satisfies for the case of the high gain loop of the equations (26), (30) and (34).

Also, whether the PLL has a high gain loop or a low gain loop, or whether a filter is a passive lag-lead filter, an active lag-lead filter or an active PI filter, the time constant is of a large value, such that 1<<τ1 and 1<<τ1+τ2. Hence, the phase error transfer function Hₑ(s), shown by the equation (27), (31) or (35), may be approximated by

$${H}_{e} ( s ) \approx \frac{{s}^{2}}{{s}^{2} + 2 s {ξω}_{n} + {ω}_{n}^{2}} \qquad ( 39 )$$

In the denominators of the phase error transfer functions Hₑ(s), shown by the equations (27), (31) and (35), there are contained terms of s other than the term s².

In case these terms of s are disregarded, the phase error transfer function Hₑ(s), shown by the equation (27), (31) or (35), is the equation (39).

In case of large values of τ1 and τ1+τ2 (1<<τ1 or 1<<τ1+τ2), the terms of s may be disregarded and the above phase error transfer function may be expressed by the approximation (39). However, even if the values of τ₁ and τ₁+τ₂ are small, simply the result deviates from the equation (19).

FIG. 9 shows, for reference sake, the amplitude characteristics of the approximation (39) to be used in place of the phase error transfer function Hₑ(s).

Since the maximum value of the orders of s of the denominator of the transfer function is 2, the transfer function is known as a second-order loop.

Also, in a known manner, the amplitude characteristics |H(jω)| of the loop transfer function H(jω), shown by the equation (38), are those of the second-order LPF, while the amplitude characteristics |Hₑ(jω)| of the phase error transfer function Hₑ(jω) shown by the equations (27), (31) or (35) or the amplitude characteristics |Hₑ(jω)| of the phase error transfer function Hₑ(jω) shown by the equation (39) are those of the second-order HPF.

Hence, the transfer characteristics H(s) has a −3 dB cut-off frequency ω_{-3 dB}, where ω_{-3 dB} represents a closed loop band of the PLL circuit.

If, in a high gain loop, the amplitude characteristics |Hₑ(jω)| are set so that

$$\vert H ( jω ) \vert = \frac{1}{\sqrt{2}}$$

and the equation is solved for ω, the −3 dB cut-off frequency ω_{-3 dB} may be found by

$$\begin{matrix}{ω}_{- 3 dB} = {ω}_{n} \sqrt{2 {ξ}^{2} + 1 + \sqrt{1 + {( 2 {ξ}^{2} + 1 )}^{2}}} \\ = {ω}_{n} \sqrt{2 {ξ}^{2} + 1 + \sqrt{4 {ξ}^{4} + 4 {ξ}^{2} + 2}}\end{matrix} \qquad ( 40 )$$

As for this sort of the PLL and the frequency setting circuit for the gm-filter circuit, employing the PLL, reference may be made to Non-Patent Document 1 (F. Krummenacher and N. Joehl, “A 4-MHz CMOS Continuous-Time Filters with On-Chip Automatic Tuning” IEEE J. Solid-State Circuits, Vol. SC-23, No. 3, pp-750-758, June 1988).

Referring to FIG. 10, showing the circuit of Non-Patent Document 1, a PLL circuit is constituted by using, as a VCO circuit (gm-C VCO), a gm-C master filter circuit 301, made up of an OTA and a capacitor. A control voltage VCON, a DC voltage corresponding to the phase difference between the output of the VCO circuit and the reference frequency f_{REF}, is derived via a PD 303 and an LPF 304. The value of the transconductance gm of the OTA, forming the gm-C master filter circuit in the VCO, is controlled so that the reference frequency fREF will be equal to the VCO oscillation frequency. The value of the transconductance gm of the OTA, forming the gm-C slave filter circuit 302, is controlled with the same control voltage VCON to set predetermined frequency characteristics. This tuning system is used extensively.

With the VCO circuit (gm-C VCO), shown in FIG. 10, a BPF output signal is fed back to a BPF input signal with the use of a second-order BPF (band-pass filter) circuit. Hence, the oscillation frequency of the VCO circuit is the center frequency of the BPF. It is necessary to provide the condition for stabilized oscillations and to use a non-linear resistance to implement a negative resistance −R.

The oscillation frequency is varied due to fluctuations in the conditions and, in general, the fluctuations occur over a broader range.

Inherently, the function of oscillations in a gm-C master filter circuit (gm-C VCO) 301 and the function of filtering in a gm-C slave filter circuit (gm-C filter) 302 represent different phenomena and are felt to be compatible with each other only to a limited extent.

If the both functions of the gm-C master filter circuit (gm-C VCO) 301 and the gm-C slave filter circuit (gm-C filter) 302 are the filtering functions, the two are felt to be more compatible with each other.

This is made possible by a method of using a VCF in the PLL circuit, as disclosed in Non-Patent Document 2 (V. Gopinathan, Y. P. Tsividis K.-S. Tan, and R. K. Hestler, “Design Considerations for High-Frequency Continuous-Time Filters and Implementation of an Antialiasing Filter for Digital Video”, IEEE J. Solid-State Circuits, Vol. 25, No. 6, pp. 1368-1378, December 1990).

As a concrete example of the circuitry, a PLL circuit shown in FIG. 11 is used. That is, a gm-C master filter circuit 101, as a first-order LPF (first-order gm-C LPF), constituted by an OTA and a capacitor, is used as a phase shifter for causing the phase shifting of 0° to 90°, and an XNOR (exclusive-NOR) circuit 105 is used as a phase detector. A DC voltage corresponding to the phase difference between two input signals is obtained via a loop filter (first-order LPF) 107. The control voltage is varied to vary the gm (transconductance) of the OTA to provide a setting value of the phase difference from the input reference frequency of 0° to 90°, which is 45° in the case of Patent Document 1 (JP Patent Kokai JP-A-2005-328272) by the same inventor as the present inventor. This allows setting the cut-off frequency of the gm-C filter circuit 103 to a preset value.

In the related art Publications, there are many statements to the effect that the first-order LPF shall be used as a 90° phase shifter. With the first-order LPF, however, it is well-known to be theoretically not possible for the phase difference to get to 90°, such that 0°<θ<90°. Hence, the first-order LPF cannot be used as a 90° phase shifter.

The phase detector is to output a signal corresponding to the phase difference between two input signals. In case the phase detector outputs a product of the two input signals, a multiplier may be used. However, an XNOR circuit, which is a simple digital circuit, or an XOR circuit which also is a simple digital circuit, may likewise be used, as shown in FIG. 11.

With use of the phase detector, making use of the multiplier, XOR circuit or the XNOR circuit, it is possible to construct the simplest phase locked loop (PLL). In case the phase difference between the two input signals is 90° (π/2), the loop is pulled into a locked state, as taught in many textbooks.

For example, with use of an XOR circuit, as a phase detector, the DC voltage of an output signal is VDD/2 when the phase difference between the two input signals is 90° (π/2), at which time the loop is pulled into a locked state.

The frequency of the output signal is then twice the frequency of the two input signals, though the two signals differ in phase by 90°. That is, in the simplest phase locked loop (PLL), making use of the XOR circuit as the phase detector, the phase difference from the reference frequency is 90° (π/2).

It may thus be seen that, in case the PLL is implemented to generate the phase difference of 90°, the phase variable devices, that is, the devices whose phase may advance or lag by 90°, for example, differentiators, integrators or filters, may be used, in addition to the VCO circuit.

However, in FIG. 11, in which the first-order LPF (first-order gm-C LPF) 101 is used as a phase shifter, as described above, the phase difference of 90° may not be achieved.

Hence, an output signal of the loop filter 107 is received via OP amp 108, and a reference voltage VDD/4, matched to the phase difference of 45°, as set, is applied as the reference voltage for the OP amp 108.

Or, if the phase difference is set to 90°, the reference voltage of the OP amp is to be set to VDD/2, matched to the phase difference of 90° as set. In ordinary textbooks, there sometimes appear the statements to such effect. However, it is not possible in actuality to set the phase lag of the PLL loop so as to be within a range of 180°.

That is, the phase delay of the PLL loop exceeds 180° to render it impossible to constitute a negative feedback loop and hence to design a PLL circuit.

In order to avert this, Patent Document 1 by the same inventor as the present inventor (JP Patent Kokai JP-A-2005-328272) sets the setting value for the phase difference from the input reference frequency of from 0° to 90°, to 45°, and applies the reference voltage of VDD/4, matched to the phase difference of 45°.

By so doing, the cut-off frequency of the gm-C filter 102 of FIG. 11 may be set to a predetermined value.

However, even in this case, the phase is delayed by 0° to 90°, because the first-order LPF is used as the gm-C master filter circuit 101.

Thus, if the phase margin of the PLL loop is taken into account, there is no alternative but to use a lag-lead filter as the loop filter 107, and to set the phase delay so as to be smaller than 90°.

Even though the phase margin may be maintained in this manner, the quantity of attenuation of the amplitude value in the high frequency range is determined by the resistance ratio of two resistors R1 and R2 (see FIG. 3A), because the loop filter 107 used is a lag-lead filter. Hence, the reference frequency component cannot be decreased to a sufficiently small value.

### [Patent Document 1]

JP Patent Kokai JP-A-2005-328272

### [Patent Document 2]

JP Patent Kokai JP-A-2005-223439

### [Non-Patent Publication 1]

F. Krummenacher and N. Joehl, ‘A 4-MHz CMOS Continuous-Time Filters with On-Chip Automatic Tuning”, IEEE J. Solid-State Circuits, Vol. SC-23, No. 3, pp. 750-758, June 1988

### [Non-Patent Document 2]

V. Gopinathan, Y. P. Tsividis K.-S. Tan, and R. K. Hestler, “Design Considerations for High-Frequency Continuous-Time Filters and Implementation of an Antialiasing Filter for Digital Video”, IEEE J. Solid-State Circuits, Vol. 25, No. 6, pp. 1368-1378, December 1990

### [Non-Patent Document 3]

K. Bult and H. W. Walling a, “A CMOS Analog Continuous-Time Delay Line with Adaptive Delay-Time Control”, IEEE J. Solid-State Circuits, Vol. SC-23, No. 3, pp. 759-766, June 1988

### SUMMARY OF THE DISCLOSURE

The conventional circuits, described above, suffer from the following problems:

The first problem is that the reference frequency component cannot be decreased to a sufficiently low value.

It is because the conventional circuits use a lag-lead filter,

The second problem is that the phase margin within the PLL loop is not sufficient.

It is because the phase rotation by 90° occurs both in the VCO and in the phase shifter.

In view of the above depicted problems of the related art, it is an object of the present invention to provide a PLL circuit in which a reference frequency component at a loop filter output can be decreased to a sufficiently small value and in which the phase margin in the PLL loop may be assured, and a frequency setting circuit that makes use of the PLL circuit.

In the PLL circuit and the frequency setting circuit, according to the present invention, an output signal from a frequency oscillator (VCO or ICO), the oscillation frequency of which is controlled by an electrical signal, is supplied to one input terminal of a phase detector via a high pass filter (HPF). A reference frequency is supplied to the other input terminal of the phase detector. An output signal of the phase detector is passed through a loop filter whereby the DC component of the signal is generated and output as the aforementioned electrical signal that controls the frequency oscillator.

According to the present invention, an inverted signal of an output signal of the frequency oscillator (VCO or ICO), the oscillation frequency of which is controlled by an electrical signal, is generated and delivered to one input terminal of the phase detector via a delay circuit. The reference frequency is supplied to the other input terminal of the phase detector. An output signal of the phase detector is passed through a loop filter whereby the DC component of the signal is generated and output as the aforementioned electrical signal that controls the frequency oscillator.

According to the present invention, a frequency divider is connected between the frequency oscillator and the phase detector.

According to the present invention, the frequency oscillator is made up of a plurality of OTAs and a capacitor.

Or, according to the present invention, the PLL circuit includes a phase locked loop (PLL) including, in turn, a phase shifter, made up of a plurality of OTAs and a capacitor, and a phase detector. The phase shifter is supplied with an AC signal of a preset frequency, and the phase detector is supplied with an input signal to the phase shifter and an output signal from the phase shifter to deliver an output signal matched to the phase difference between the input signals. The transconductance (gm) of at least one of the OTAs that make up the phase shifter is varied, with the DC voltage of the output signal of the phase shifter as a control signal, to exercise control to provide for a constant value of the phase difference at the phase shifter. The phase in the phase shifter advances.

According to the present invention, the PLL circuit includes a phase locked loop (PLL) including, in turn, a phase shifter, made up of a plurality of OTAs and a capacitor, and a phase detector. The phase shifter is supplied with an AC signal of a preset frequency, and the phase detector is supplied with an input signal to the phase shifter and an output signal from the phase shifter to deliver an output signal matched to the phase difference between the input signals. The DC voltage of the output signal of the phase shifter is amplified by an amplifier. The transconductance (gm) of at least one of the OTAs that make up the phase shifter is varied, with the amplified DC voltage of the output signal of the phase shifter as a control signal, to exercise control to provide for a constant value of the phase difference at the phase shifter. The phase in the phase shifter advances.

According to the present invention, the PLL circuit includes a phase locked loop (PLL) including, in turn, a phase shifter, made up of a plurality of OTAs and a capacitor, and a phase detector. The phase shifter is supplied with an AC signal of a preset frequency, and the phase detector is supplied with an input signal to the phase shifter and an output signal from the phase shifter to deliver an output signal matched to the phase difference between the input signals. The DC voltage of the output signal of the phase shifter is converted by a V-I converter into the current. The transconductance (gm) of at least one of the OTAs that make up the phase shifter is varied, with the current output of the V-I converter as a control signal, to exercise control to provide for a constant value of the phase difference at the phase shifter. The phase in the phase shifter advances.

According to the present invention, the PLL circuit includes a phase locked loop (PLL) including, in turn, a phase shifter, made up of a plurality of OTAs and a capacitor, and a phase detector. The phase shifter is supplied with an AC signal of a preset frequency, and the phase detector is supplied with an input signal to the phase shifter and an output signal from the phase shifter to deliver an output signal matched to the phase difference between the input signals. The DC voltage of the output signal of the phase shifter is converted by a V-I converter into the current via an amplifier that amplifies the DC voltage of the output signal of the phase shifter. The transconductance (gm) of at least one of the OTAs that make up the phase shifter is varied, with the current output of the V-I converter as a control signal, to exercise control to provide for a constant value of the phase difference at the phase shifter. The phase in the phase shifter advances.

According to the present invention, the PLL circuit includes a second-order high pass filter (HPF).

According to the present invention, the PLL circuit includes a first-order high pass filter (HPF).

According to the present invention, the loop filter is made up of an RC first-order low pass filter (LPF). Alternatively, according to the present invention, the loop filter is made up of a cascaded connection of a lag-lead filter and a first-order low pass filter (LPF).

According to the present invention, there is provided a gm-C filter including a plurality of OTAs controlled in common by a control signal from the PLL circuit.

The meritorious effects of the present invention are summarized as follows.

The first meritorious effect of the present invention is that the reference frequency can be removed sufficiently. The reason is that, according to the present invention, there is no necessity of using the lag-lead filter.

The second meritorious effect of the present invention is that the loop is stabilized. The reason is that, according to the present invention, the phase delay of 90° is canceled out.

Still other objects and advantages of the present invention will become readily apparent to those skilled in this art from the following detailed description in conjunction with the accompanying drawings wherein only the preferred examples of the invention are shown and described, simply by way of illustration of the best mode contemplated of carrying out this invention. As will be realized, the invention is capable of other and different examples, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram showing the configuration of a PLL circuit employing a conventional VCO.

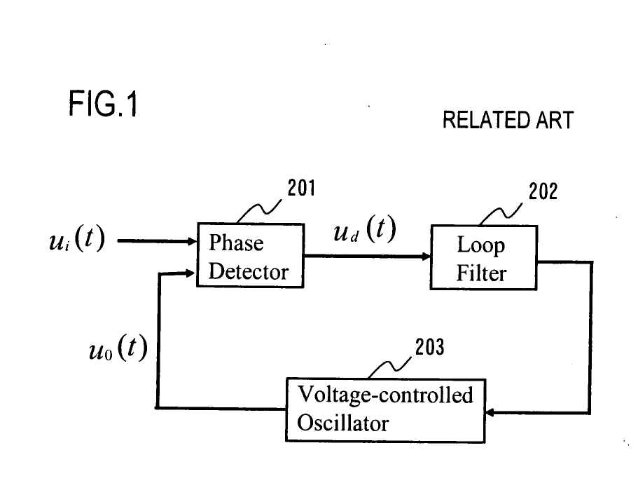

FIG. 2 is a diagram showing a linear PLL circuit model employing a conventional VCO.

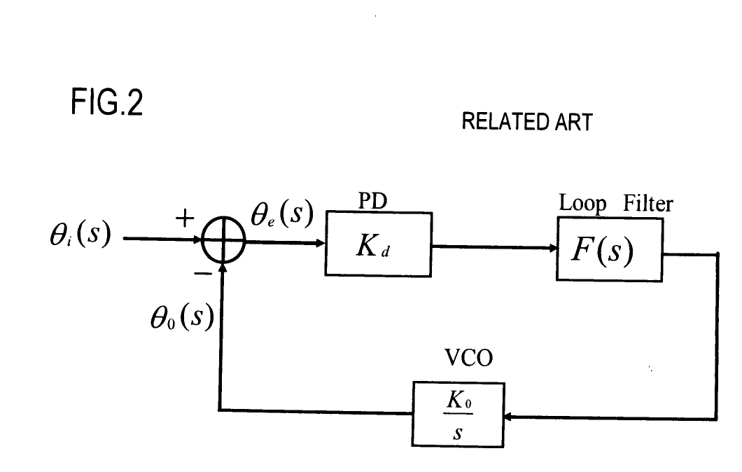

FIGS. 3A, 3B and 3C are diagrams showing various loop filters used in a conventional PLL circuit.

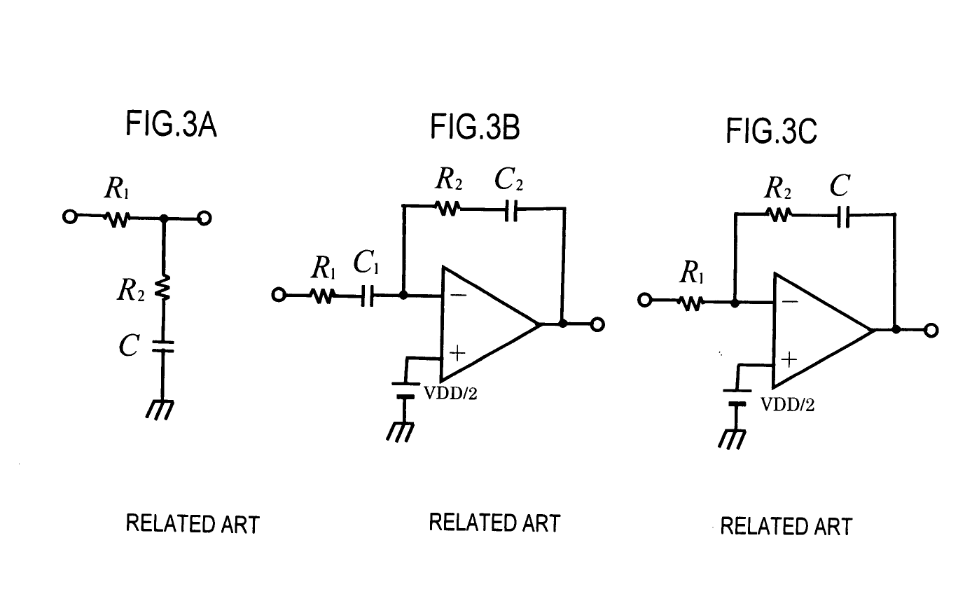

FIG. 4 is a graph showing amplitude characteristics of closed-loop transfer functions of the PLL circuit employing a conventional VCO.

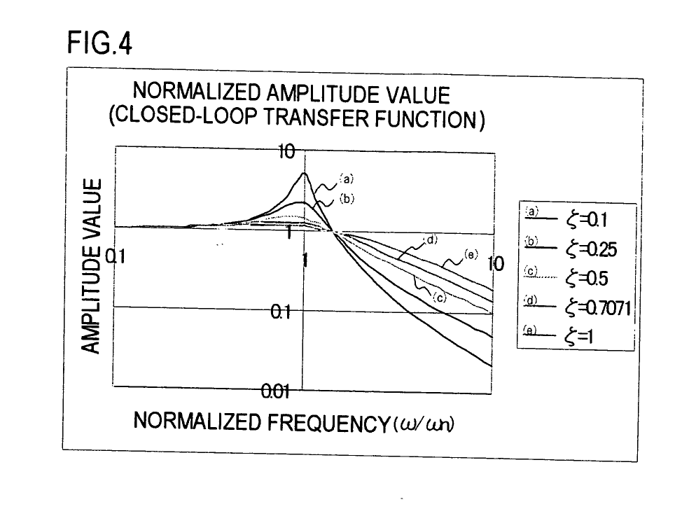

FIG. 5 is a graph showing amplitude characteristics of the phase error transfer functions of the PLL circuit employing a conventional VCO.

FIG. 6 is a diagram showing the configuration of the PLL circuit employing a conventional VCF.

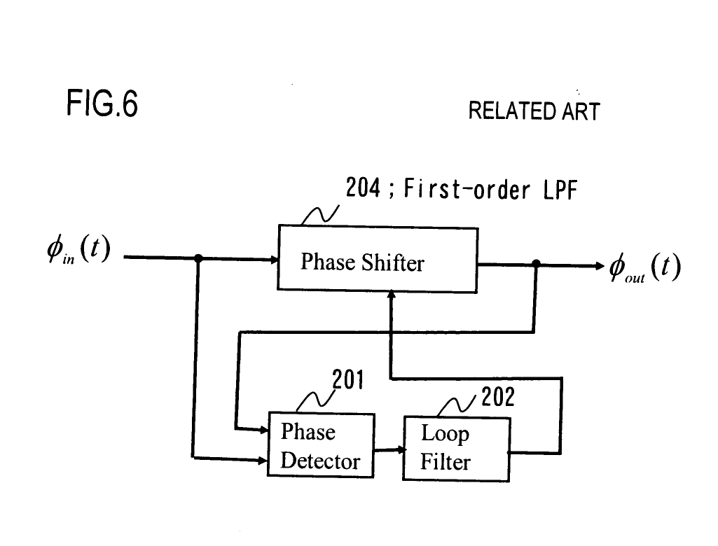

FIG. 7 is a diagram showing a linear PLL circuit model employing a conventional VCF.

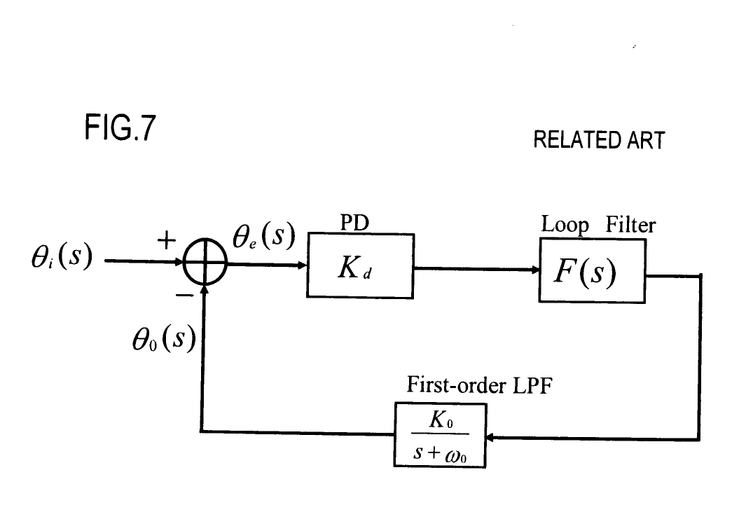

FIG. 8 is a graph showing amplitude characteristics of closed-loop transfer functions of the PLL circuit employing a conventional VCF.

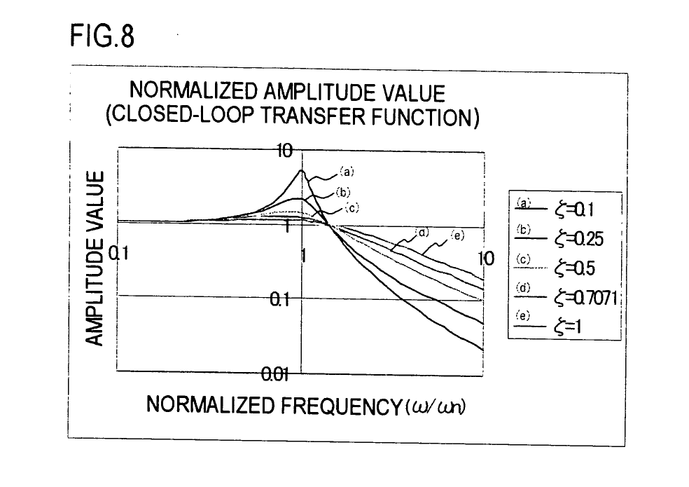

FIG. 9 is a graph showing amplitude characteristics of phase error transfer functions of the PLL circuit employing a conventional VCF.

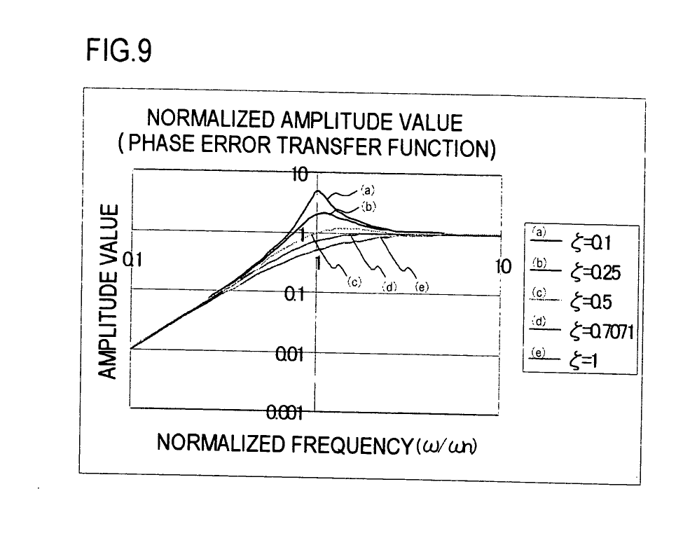

FIG. 10 is a diagram showing a configuration of a gm-C filter circuit in which a PLL circuit employing a conventional VCF as a control circuit.

FIG. 11 is a diagram showing another configuration of a gm-C filter circuit in which a PLL circuit that makes use of the conventional VCF is used as a control circuit.

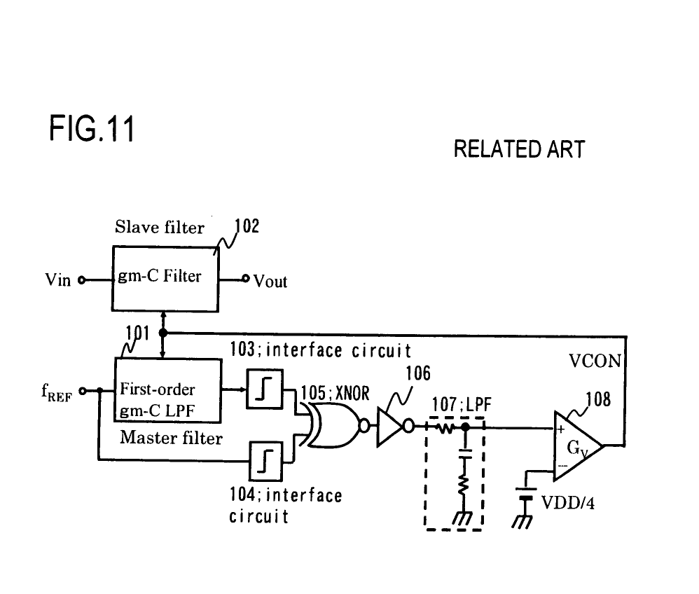

FIG. 12 is a diagram showing the configuration of a first PLL circuit employing a VCO of the present invention.

FIG. 13 is a diagram showing a first linear PLL circuit model employing a VCO of the present invention.

FIGS. 14A, 14B and 14C are diagrams showing various configurations of the loop filter circuits used in the PLL circuit of the present invention.

FIG. 15 is a graph showing amplitude characteristics of closed-loop transfer functions of the first PLL circuit employing a VCO of the present invention.

FIG. 16 is a graph showing amplitude characteristics of phase error transfer functions of the first PLL circuit employing a VCO of the present invention.

FIG. 17 is a diagram showing the configuration of a second PLL circuit employing a VCO of the present invention.

FIG. 18 is a diagram showing the configuration of a second linear PLL circuit model employing a VCO of the present invention.

FIG. 19 is a graph showing amplitude characteristics of closed-loop transfer functions of the second PLL circuit employing a conventional VCF.

FIG. 20 is a graph showing amplitude characteristics of phase error transfer functions of the PLL circuit employing a conventional VCF.

FIGS. 21A, 21B and 21C are diagrams showing various loop filters (second-order LPFs) used in the PLL circuit according to the present invention.

FIG. 22 is a diagram showing a third PLL circuit employing the VCO of the present invention, an inverter and a delay circuit.

FIG. 23 is a diagram showing a fourth PLL circuit employing the VCO of the present invention and a frequency divider.

FIG. 24 is a diagram showing a fifth PLL circuit employing the VCO of the present invention, an inverter, a delay circuit and a frequency divider.

FIG. 25 is a diagram showing the configuration of a first PLL circuit employing a VCF according to the present invention.

FIG. 26 is a diagram showing a first linear PLL circuit model employing a VCF according to the present invention.

FIG. 27 is a graph showing amplitude characteristics of closed-loop transfer functions of the first PLL circuit employing a VCF according to the present invention.

FIG. 28 is a graph showing amplitude characteristics of phase error transfer functions of the first PLL circuit employing a VCF according to the present invention.

FIG. 29 is a diagram showing the configuration of a second PLL circuit employing a VCF according to the present invention.

FIG. 30 is a diagram showing a second linear PLL circuit model employing a VCF according to the present invention.

FIG. 31 is a graph showing amplitude characteristics of closed-loop transfer functions of the second PLL circuit employing a VCF according to the present invention.

FIG. 32 is a graph showing amplitude characteristics of phase error transfer functions of the second PLL circuit employing a VCF according to the present invention.

FIG. 33 is a diagram showing an example of a frequency setting circuit for a gm-C filter in which a PLL circuit employing the VCO of the present invention is used as a control circuit.

FIG. 34 is a diagram showing a first example of a frequency setting circuit for a gm-C filter in which a PLL circuit employing a VCF of the present invention is used as a control circuit.

FIG. 35 is a diagram showing a second example of a frequency setting circuit for a gm-C filter in which a PLL circuit employing a VCF of the present invention is used as a control circuit.

FIG. 36 is a diagram showing an example of a second-order gm-C HPF.

FIG. 37 is a diagram showing an example of a first-order gm-C HPF.

FIG. 38 is a diagram showing an example of an OTA.

FIG. 39 is a diagram showing an example of the configuration that converts a control voltage into the current to control the OTA.

### PREFERRED MODES OF THE INVENTION

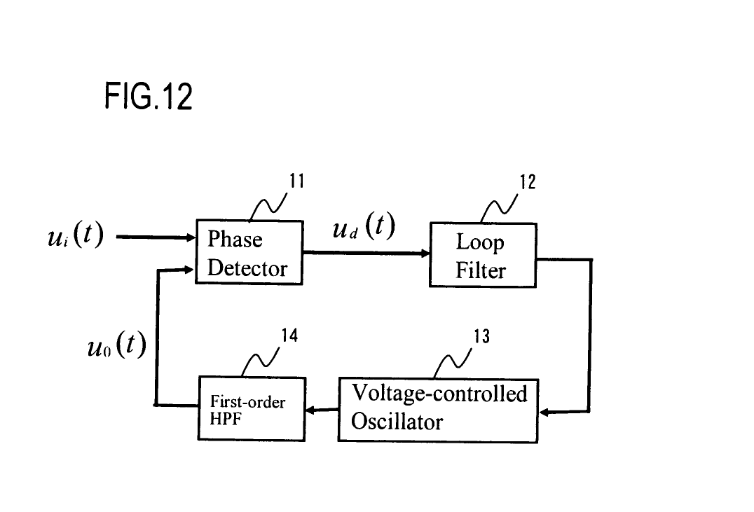

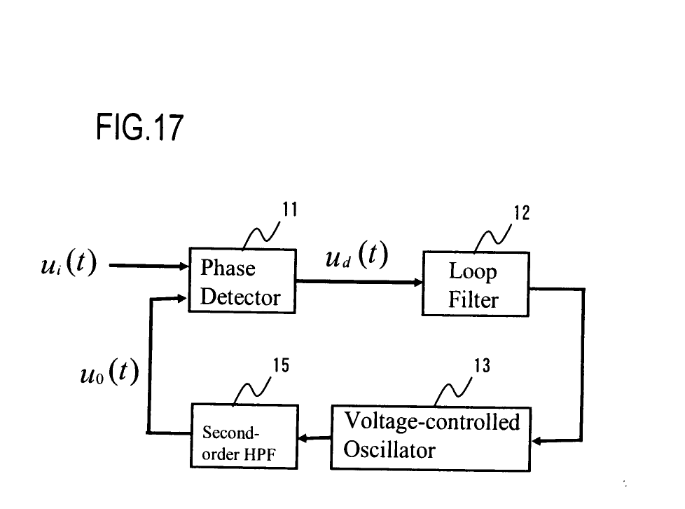

The present invention is now described in detail with reference to the accompanying drawings. In one aspect, the present invention provides a PLL circuit comprising a frequency oscillator (13), the oscillation frequency of which is controlled by an electrical signal, a high pass filter (HPF) (a first-order HPF 14/a second-order HPF 15) receiving an output signal of the frequency oscillator, a phase detector (11) receiving an output (uₒ(t)) of the high pass filter (HPF) at its input terminal and receiving a reference frequency (uᵢ(t)) at its other input terminal, and a loop filter (12) receiving an output signal (u_{d}(t)) of the phase detector. A DC component from the loop filter is supplied as the electrical signal to the frequency oscillator (13) (see FIG. 12/FIG. 17).

In another aspect, the present invention provides a PLL circuit comprising

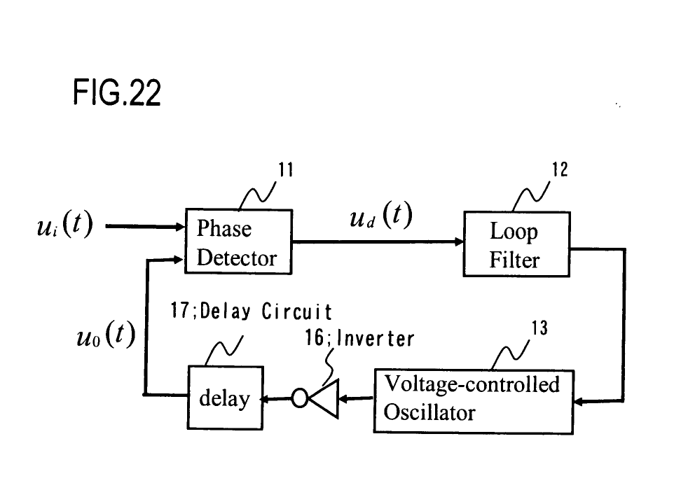

a frequency oscillator (13), the oscillation frequency of which is controlled by an electrical signal, a delay circuit (17) for delaying an inverted signal of an output signal of the frequency oscillator, a phase detector (11) receiving an output of the delay circuit at its one input terminal and receiving a reference frequency at its other input terminal, and a loop filter (12) receiving an output signal of the phase detector. A DC component from the loop filter is supplied as the electrical signal to the frequency oscillator (13) (see FIG. 22).

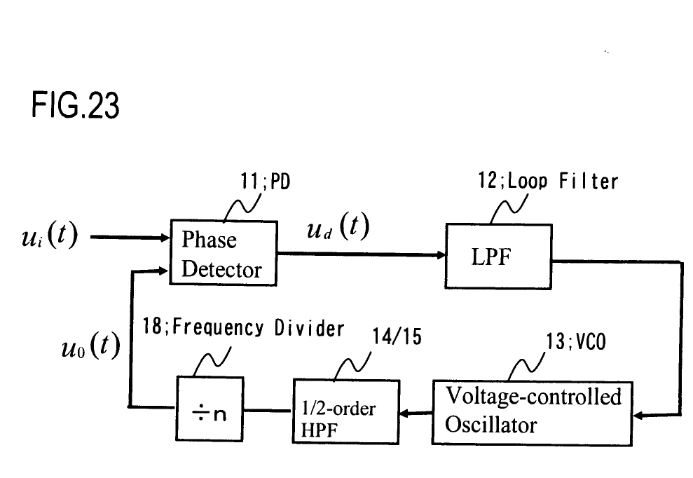

According to the present invention, a frequency divider (18) is connected between the frequency oscillator (13) and the phase detector (11) (see FIG. 23).

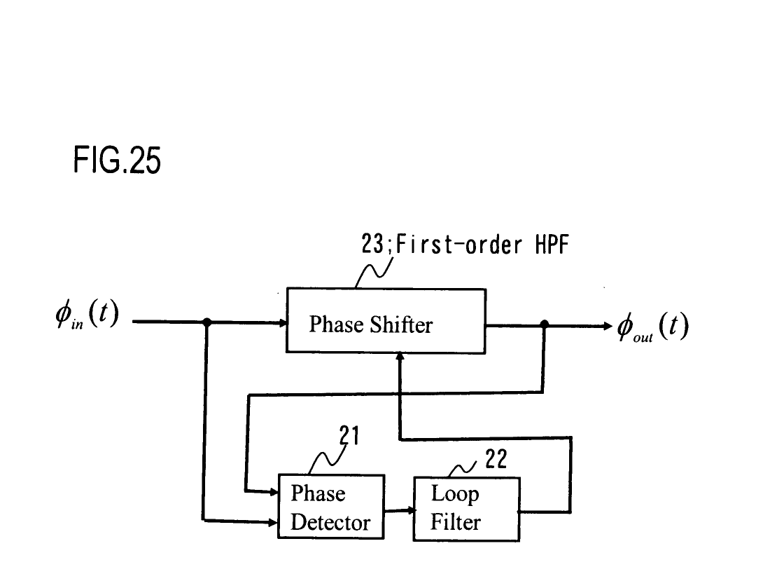

In a further aspect, the present invention provides a PLL circuit comprising a phase locked loop (PLL) including a phase shifter (23/24), a phase detector (21) and a loop filter (22). The phase shifter includes a plurality of OTAs (operational transconductance amplifiers) and a capacitor and is configured to receive an AC signal of a preset frequency. The phase detector receives an input signal to the phase shifter (23/24) and an output signal from the phase shifter (23/24) and outputs a signal corresponding to the phase difference between the signals. The loop filter receives an output signal of the phase detector (21). The phase locked loop (PLL) varies the transconductance (gm) of at least one of the OTAs that make up the phase shifter (23/24), with a DC voltage of an output signal of the loop filter as a control signal, to exercise control to render the phase difference at the phase shifter (23/24) constant. The phase advances in the phase shifter (23/24) (see FIGS. 25/29).

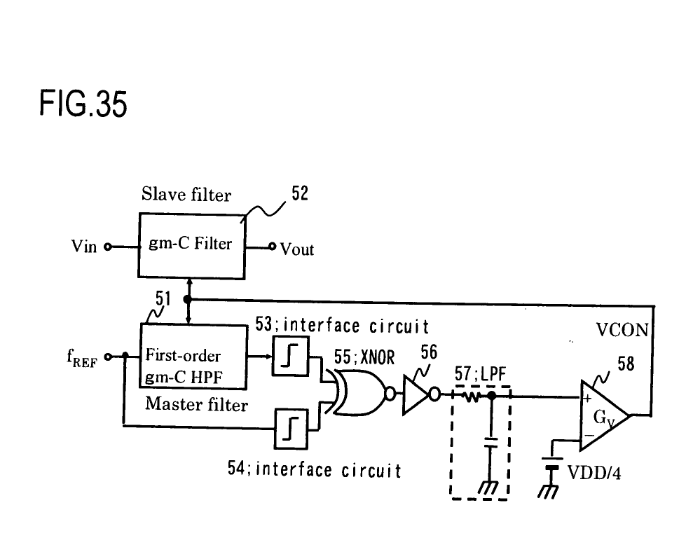

In a further aspect, the present invention provides a PLL circuit comprising a phase locked loop (PLL) including a phase shifter (51), a phase detector (53, 54, 55, 56) and a loop filter (57). The phase shifter includes a plurality of OTAs (operational transconductance amplifiers) and a capacitor and is configured to receive an AC signal of a preset frequency. The phase detector receives an input signal to the phase shifter and an output signal from the phase shifter and outputs a signal corresponding to the phase difference between the input signals. The loop filter receives an output of the phase detector. The DC voltage from the loop filter is amplified by an amplifier (58). The transconductance (gm) of at least one of the OTAs that make up the phase shifter (51) is varied, with the amplified DC voltage of the output signal of the loop filter as a control signal, to exercise control to provide for a constant value of the phase difference at the phase shifter. The phase in the phase shifter (51) advances (FIG. 35). The DC voltage from the loop filter may also be converted by a voltage-current converter (V-I converter) into the current, in which case the transconductance (gm) of at least one of the OTAs that constitute the phase shifter is varied, with the output current of the voltage-current converter as a control signal, to exercise control to provide for a constant value of the phase difference at the phase shifter.

With the PLL circuit of the present invention, and the frequency setting circuit, that makes use of the PLL circuit, the reference frequency component at the loop filter output can be decreased sufficiently, while the phase margin within the PLL loop may be maintained. The phase shift quantity in the first-order gm-C high pass filter, used as a phase shifter, may be constant despite manufacture tolerances or temperature characteristics of the transistors or manufacture tolerances of the capacitors. As a result, the cut-off frequency of the first-order gm-C high pass filter, used as a phase shifter, may be constant. By using the same control signal, the cut-off frequency of the first-order gm-C filter may be constant despite manufacture tolerances or temperature characteristics of the transistors or manufacture tolerances of the capacitors.

### FIRST EXAMPLE

FIG. 12 shows an example of the present invention in which a first-order HPF 14 is inserted on an output side of a VCO circuit 13. In the VCO circuit 13, the oscillation frequency is substantially sinusoidal. The reason is that a high Q is achieved in the oscillator so that the spectrum of the oscillation frequency will be a single spectrum such that only minor values of harmonic components are contained in an output waveform.

Since the oscillation waveform is sinusoidal, no pulse components are generated on differentiating the waveform through the first-order HPF 14. The resulting waveform is a sine wave with a phase lead of 90°.

If the waveform is rendered into a rectangular waveform and subjected to phase comparison with the reference frequency having the rectangular waveform, it is not possible for two input terminals of the phase detector 11 to distinguish between the two waveforms. Hence, the phase detector used in the conventional circuit may be used unchanged.

However, the phase delay of 90° occurs at the VCO 13. Consequently, the first-order HPF 14 is inserted at an output of the VCO to cancel out the phase delay.

If the VCO 13 and the first-order HPF 14 are deemed to be a combined oscillator, the oscillator is, as it were, delivering an oscillation waveform having a phase lead of 90°.

That is, the phase delay of the PLL loop is only that produced at a loop filter 12.

Thus, even if the loop filter 12 is a first-order LPF (RC filter), where the phase delay of 90° is produced, the phase range of from −180° to 180° may be maintained, so that there is no need to use a lag-lead filter.

In FIG. 12, a reference frequency uᵢ(t) and an output uₒ(t) of the first-order HPF 14 are supplied to a phase detector (PD) 11. An output u_{d}(t) of the phase detector 11 is supplied to the loop filter 12 where AC component is eliminated. Hence, the DC component is delivered as a control voltage to the VCO 13. An output of the VCO 13 is supplied to the first-order HPF 14 from which the uₒ(t) is output.

The operation of the present example is now described. In FIG. 12, the reference frequency uᵢ(t) and the output uₒ(t) of the first-order HPF 14 are supplied to the phase detector 11 where the phase difference between the two waveforms is detected. Both the DC component and the AC component are contained in the output u_{d}(t) of the phase detector 11. The AC component is removed by the loop filter 12, and the DC component is delivered as a control voltage to the VCO 13. The present example exercises control so that the waveform of the oscillation frequency of the VCO 13 has a phase equal to the phase of the waveform of the reference frequency.

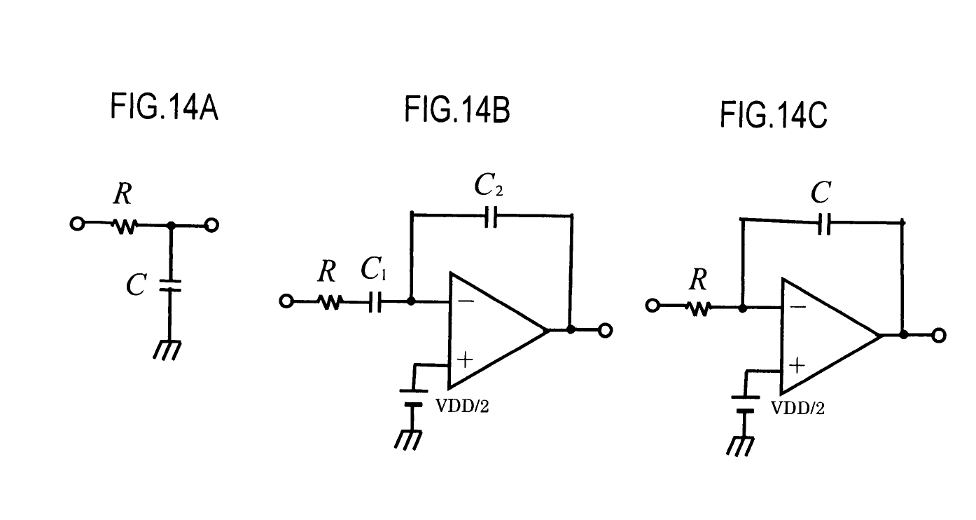

The output of the VCO 13 is supplied to the first-order HPF 14 from which it is output as uₒ(t) with the phase lead of 90°. In a simple form, the first-order HPF 14 may, for example, be designed by a capacitor C and a resistor R. For example, the first-order HPF 14 may be implemented by interchanging the resistor R and the capacitor C in FIG. 14A.

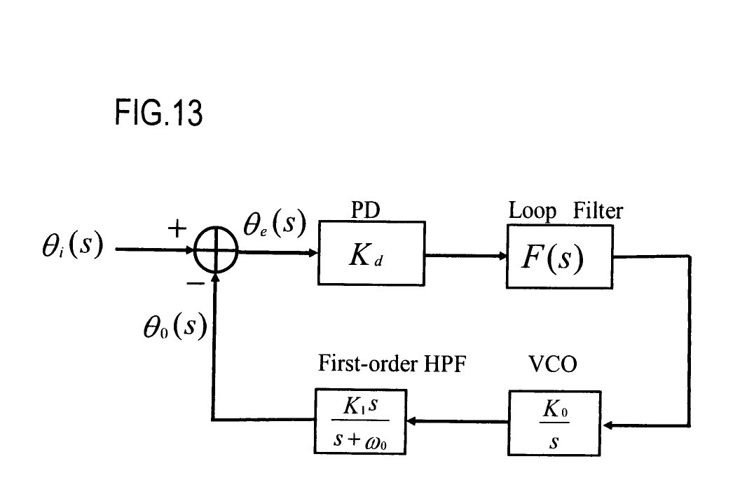

The PLL circuit, shown in FIG. 12, may be revised to a linear PLL circuit model shown in FIG. 13. In FIG. 13, the closed-loop transfer function H(s) of the PLL circuit may, on the basis of the control theory, be defined by the following equation (41):

$$H ( s ) ≡ \frac{{θ}_{0} ( s )}{{θ}_{i} ( s )} = \frac{{K}_{d} {K}_{0} F ( s ) G ( s )}{s + {K}_{d} {K}_{0} F ( s ) G ( s )} \qquad ( 41 )$$

In the above equation,

Kd[V/rad] is the gain of the phase detector (PD),

F(s) is a transfer function of a loop filter (LP),

K₀[rad/s-V] is a gain factor of the VCO, and

G(s) is a transfer function of the HPF introduced.

A phase transfer function is further added. The phase error transfer function Hₑ(s) is defined by the following equation (42):

$${H}_{e} ( s ) ≡ \frac{{θ}_{e} ( s )}{{θ}_{i} ( s )} = \frac{s}{s + {K}_{d} {K}_{0} F ( s ) G ( s )} \qquad ( 42 )$$

The transfer function G(s) of the first-order HPF inserted is

$$G ( s ) = \frac{{K}_{1} s}{s + {ω}_{0}} \qquad ( 43 )$$

In the present example, an RC first-order LPF is used as the loop filter 12. Therefore, in the case of a passive RC filter, shown in FIG. 14A, its transfer function F(s) is

$$F ( s ) = \frac{1}{1 + s τ} \qquad ( 44 )$$

where τ=RC.

In the case of an active RC filter, shown in FIG. 14B, its transfer function F(s) is

$$F ( s ) = {K}_{a} \frac{1}{1 + s τ} \qquad ( 45 )$$

where τ=RC, and Kₐ=C₁/C₂.

In the case of an active inverting/integrating filter, shown in FIG. 14C, its transfer function F(s) is

$$F ( s ) = \frac{1}{s τ} \qquad ( 46 )$$

where τ=RC.

In the case of a passive RC filter, shown in FIG. 14A, the closed loop transfer function H(s) of the PLL circuit is

$$H ( s ) = \frac{\frac{{K}_{d} {K}_{0} {K}_{1}}{τ}}{{s}^{2} + s ( \frac{1}{τ} + {ω}_{0} ) + \frac{{K}_{d} {K}_{0} {K}_{1} + {ω}_{0}}{τ}} = \frac{{ω}_{n}^{2} - \frac{{ω}_{0}}{τ}}{{s}^{2} + 2 s {ξω}_{n} + {ω}_{n}^{2}} \qquad ( 47 )$$

and the phase error transfer function Hₑ(s) is

$$\begin{matrix}{H}_{e} ( s ) = \frac{{s}^{2} + s ( \frac{1}{τ} + {ω}_{0} ) \frac{{ω}_{0}}{τ}}{{s}^{2} + s ( \frac{1}{τ} + {ω}_{0} ) + \frac{{K}_{d} {K}_{0} {K}_{1} + {ω}_{0}}{τ}} \\ = \frac{{s}^{2} + 2 s {ξω}_{n} + \frac{{ω}_{0}}{τ}}{{s}^{2} + 2 s {ξω}_{n} + {ω}_{n}^{2}} \\ = 1 - H ( s ) .\end{matrix} \qquad ( 48 )$$

where ωₙ is a natural frequency represented by the equation (49):

$${ω}_{n} = \sqrt{\frac{{K}_{d} {K}_{0} {K}_{1} + {ω}_{0}}{τ}} \qquad ( 49 )$$

and ζ is a damping factor represented by the equation (50):

$$ξ = \frac{{ω}_{n}}{2} ( \frac{1}{τ} + {ω}_{0} ) \qquad ( 50 )$$

In the case of the active RC filter, shown in FIG. 14B, H(s) is

$$\begin{matrix}H ( s ) = \frac{\frac{{K}_{d} {K}_{0} {K}_{a} {K}_{1}}{τ}}{{s}^{2} + s ( \frac{1}{τ} + {ω}_{0} ) + \frac{{K}_{d} {K}_{0} {K}_{a} {K}_{1} + {ω}_{0}}{τ}} \\ = \frac{{ω}_{n}^{2} - \frac{{ω}_{0}}{τ}}{{s}^{2} + 2 s {ξω}_{n} + {ω}_{n}^{2}}\end{matrix} \qquad ( 51 )$$

### and Hₑ(s) is

$$\begin{matrix}{H}_{e} ( s ) = \frac{{s}^{2} + s ( \frac{1}{τ} + {ω}_{0} ) \frac{{ω}_{0}}{τ}}{{s}^{2} + s ( \frac{1}{τ} + {ω}_{0} ) + \frac{{K}_{d} {K}_{0} {K}_{a} {K}_{1} + {ω}_{0}}{τ}} \\ = \frac{{s}^{2} + 2 s {ξω}_{n} + \frac{{ω}_{0}}{τ}}{{s}^{2} + 2 s {ξω}_{n} + {ω}_{n}^{2}} \\ = 1 - H ( s )\end{matrix} \qquad ( 52 )$$

where ωₙ is a natural frequency represented by the equation (53):

$${ω}_{n} = \sqrt{\frac{{K}_{d} {K}_{0} {K}_{a} {K}_{1} + {ω}_{0}}{τ}} \qquad ( 53 )$$

and ζ is a damping factor represented by the equation (54):

$$ξ = \frac{{ω}_{n}}{2} ( \frac{1}{τ} + {ω}_{0} ) \qquad ( 54 )$$

In the case of the active inverting/integrating filter, shown in FIG. 14C, H(s) is

$$H ( s ) = \frac{\frac{{K}_{d} {K}_{0} {K}_{1}}{τ}}{{s}^{2} + {ω}_{0} s + \frac{{K}_{d} {K}_{0} {K}_{1}}{τ}} = \frac{{ω}_{n}^{2}}{{s}^{2} + 2 s {ξω}_{n} + {ω}_{n}^{2}} \qquad ( 55 )$$

### and Hₑ(s) is

$$\begin{matrix}{H}_{e} ( s ) = \frac{{s}^{2} + {ω}_{0} s}{{s}^{2} + {ω}_{0} s + \frac{{K}_{d} {K}_{0} {K}_{1}}{τ}} \\ = \frac{{s}^{2} + 2 s {ξω}_{n}}{{s}^{2} + 2 s {ξω}_{n} + {ω}_{n}^{2}} \\ = 1 - H ( s )\end{matrix} \qquad ( 56 )$$

where ωₙ is a natural frequency represented by the equation (57):

$${ω}_{n} = \sqrt{\frac{{K}_{d} {K}_{0} {K}_{1}}{τ}} \qquad ( 57 )$$

and ζ is a damping factor represented by the equation (58):

$$ξ = \frac{{ω}_{n}}{2} ( \frac{{ω}_{0} τ}{{K}_{d} {K}_{0} {K}_{1}} ) \qquad ( 58 )$$

where ωₙ and ζ are crucial parameters governing the characteristics of the PLL circuit.

If K_{d}K₀>>ωₙ or K_{d}KₐK₀>>ωₙ, this PLL system is said to be a high gain loop.

The most commonly used PLL has a high gain loop in order to improve the tracking characteristic. Whether the PLL has a high gain loop or a low gain loop, ωₙ>>°ω₀, and the time constant is of a large value, such that 1<<τ₁ and 1<<τ₁+τ₂. Hence, the equations (47) and (51) may be approximated by the equation (55) and, in any case, may be expressed by the following approximation (59):

$$H ( s ) \approx \frac{{ω}_{n}^{2}}{{s}^{2} + 2 s {ξω}_{n} + {ω}_{n}^{2}} \qquad ( 59 )$$

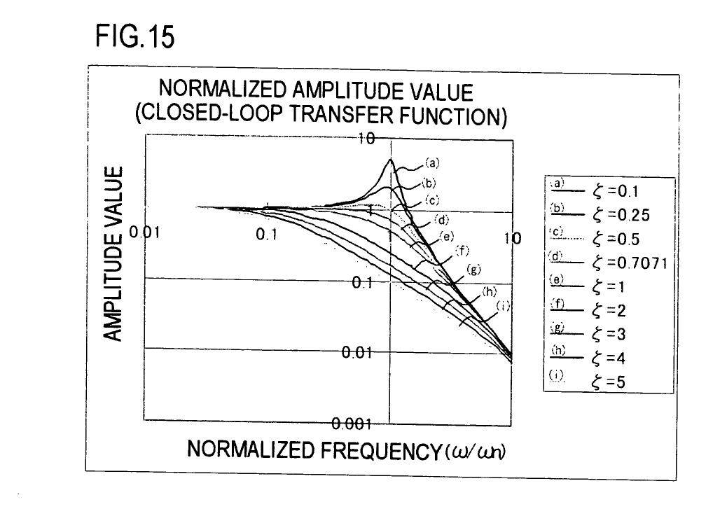

FIG. 15 shows amplitude characteristics of the closed-loop transfer function represented by the approximation (59) which is for the case of the large value of the time constant of the equations (47), (51) and (55).

Also, whether the PLL has a high gain loop or a low gain loop, or whether a filter is a passive lag-lead filter, an active RC filter or an active inverting/integrating filter, the time constant is of a large value, such that ω₀<<τ. Hence, the phase error transfer function Hₑ(s), shown by the equation (48) or (51), may be approximated by the equation (55) and shown by the following approximation (60):

$${H}_{e} ( s ) \approx \frac{{s}^{2} + 2 s {ξω}_{n}}{{s}^{2} + 2 s {ξω}_{n} + {ω}_{n}^{2}} \qquad ( 60 )$$

In the denominators of the phase error transfer functions Hₑ(s), shown by the equation (48), (51) or (55), there are contained terms of s other than the term s².

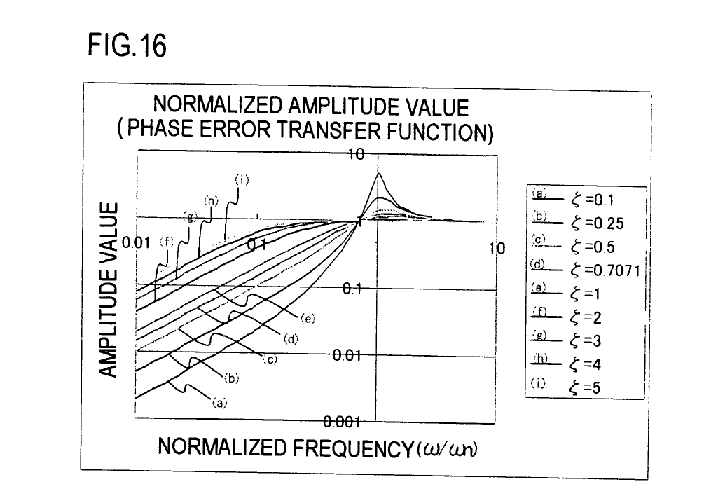

For reference sake, FIG. 16 shows amplitude characteristics of the approximation (60) which is to stand for the phase error transfer function Hₑ(s). If the damping factor ζ is changed from 0.1 to 1, the amplitude values are all zero for ω/ωₙ=1/√2. For ω/ωₙ>1/√2, the amplitude value becomes larger than unity, thus producing the overshooting.

The maximum number of the order of s in the denominator of the transfer function is 2, and hence the PLL is known as a second-order loop. In a well-known manner, the amplitude characteristic |H(jω)| of the loop transfer function H(jω), shown by the equation (59), has the characteristic of a second-order LPF, while the amplitude characteristic |Hₑ(jω)| of the phase error transfer function Hₑ(jω), shown by the equations (47), (51) and (55), or the amplitude characteristic |Hₑ(jω)| of the phase error transfer function Hₑ(jω), shown by the equation (60), has the characteristic of a second-order HPF characteristic.

Hence, the transfer function H(s) has a −3 dB cut-off frequency ω_{-3 dB}. It should be noticed that ω_{-3 dB} represents a closed loop band of the PLL circuit. If, in the high gain loop, the amplitude characteristic |Hₑ(jω)| is set so that

$$\vert H ( jω ) \vert = \frac{1}{\sqrt{2}}$$

and the transfer function is solved for ω, there may be obtained

$$\begin{matrix}{ω}_{- 3 dB} = {ω}_{n} \sqrt{1 - 2 {ξ}^{2} + \sqrt{1 + {( 2 {ξ}^{2} - 1 )}^{2}}} \\ = {ω}_{n} \sqrt{1 - 2 {ξ}^{2} + \sqrt{4 {ξ}^{4} - 4 {ξ}^{2} + 2}}\end{matrix} \qquad ( 61 )$$

Noteworthy is the fact that neither the closed loop function nor the phase error transfer function of the PLL circuit is changed no matter whether the PLL has a high gain loop or a low gain loop. It is therefore sufficient that the PLL has a high gain loop, the gain of which is just high enough to assure optimum tracking characteristic.

Similarly noteworthy is the fact that the closed loop transfer function in case of using the active inverting/integrating filter of the equation (55) as the loop filter is the transfer function of the second-order LPF itself. That is, the characteristic of the phase error transfer function in case of using the active inverting/integrating filter of the equation (56) is close to that of the second-order HPF. This relationship is the reverse of that of the case of the conventional PLL circuit that makes use of the VCO (the case of using an active PI filter for the loop filter).

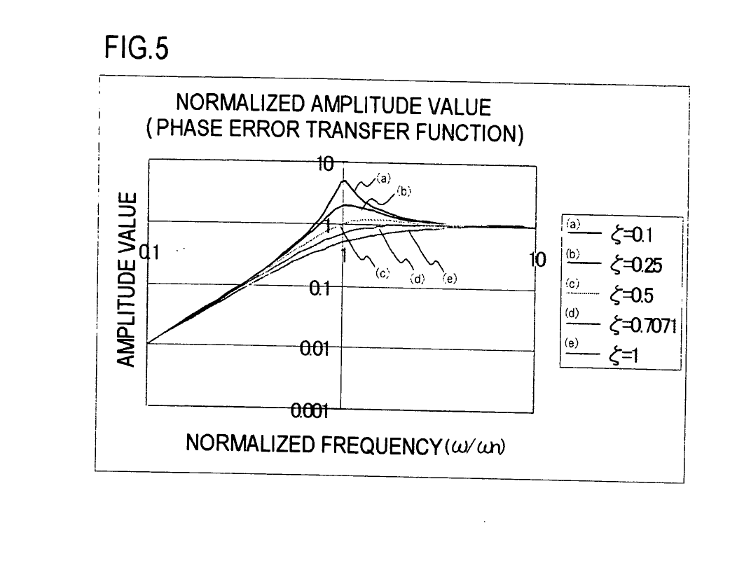

It may further be remarked that, with the conventional PLL circuit, making use of the VCO, the term of s is included in the denominator of the phase error transfer function. Thus, it may sometimes occur that fluctuations may be produced in the stop band area such that the amplitude characteristic of the phase error transfer function is closer to that shown in FIG. 15 than that shown in FIG. 5.

As for the value of the damping factor ζ, ζ=0.7071 (=1/√2) in the case of the PLL circuit making use of the conventional VCO. If, with the PLL circuit, making use of the VCO of the present example, ζ is set to ζ=5, the error of the control voltage is comprised within ±1% or less in case ω/ωₙ exceeds 0.6.

However, even if the damping factor ζ is set to a larger value, the maximum value of the control voltage exceeds a preset value to a more or less extent, without assuming a value smaller than the preset value. That is, with the PLL circuit, making use of the VCO according to the present invention, it is not proper to define ζ as a damping factor in the hitherto accepted sense of the term.

### SECOND EXAMPLE

In order to maintain a negative feedback loop, it is sufficient that the phase range is intermediate between −180° and 180°. It may therefore be contemplated to take advantage of the phase range of −180° to 0° and to insert a second-order LPF in an output of the VCO. Since the signal phase would be offset only in the delaying direction, due to e.g. the parasitic capacitance, the phase margin for −180° may presumably be maintained even when the second-order HPF is inserted as described above.

FIG. 17 shows, by way of the second example of the present invention, the configuration of a PLL circuit including a second-order HPF 15 inserted at an output of the VCO 13.

Referring to FIG. 17, a reference frequency uᵢ(t) and an output uₒ(t) of the second-order HPF 15 are supplied to a phase detector 11. An output u_{d}(t) of the phase detector 11 is supplied to a loop filter 12 where the AC component is removed and the DC component is delivered as a control voltage to the VCO 13. The output uₒ(t) is delivered from the second-order HPF 15.

The operation of the present example is now described. Referring to FIG. 17, the reference frequency uᵢ(t) and the output uₒ(t) of the second-order HPF 15 are supplied to the phase detector 11, where the phase difference between them is detected. An AC component and a DC component, as a phase error signal, are contained in the output u_{d}(t) of the phase detector 11, and are supplied to the loop filter 12, where the AC component is eliminated. Thus, the DC component is delivered as the control voltage to the VCO 13 to control the phase of the oscillation frequency of the VCO 13 so as to be equal to that of the reference frequency.

An output of the VCO 13 is supplied to the second-order HPF 15 so as to be output therefrom as uₒ(t) with a phase lead of 180°.

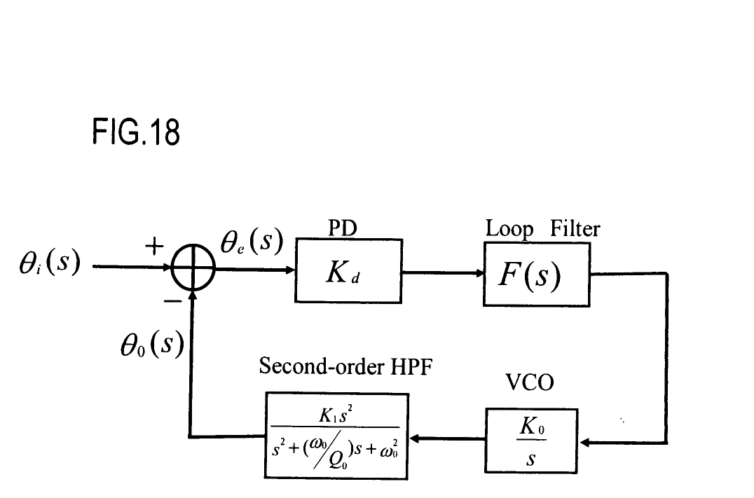

The PLL circuit, shown in FIG. 17, may be revised to a linear PLL circuit model shown in FIG. 18. In FIG. 18, the closed-loop transfer function of the PLL circuit may be defined, based on the control theory, by the following equation (62):

$$H ( s ) ≡ \frac{{θ}_{0} ( s )}{{θ}_{i} ( s )} = \frac{{K}_{d} {K}_{0} F ( s ) G ( s )}{s + {K}_{d} {K}_{0} F ( s ) G ( s )} \qquad ( 62 )$$

In the above equation,

Kd[V/rad] is the gain of a phase detector (PD),

F(s) is a transfer function of a loop filter (LP),

K₀[rad/s-V] is a gain factor of the VCO, and

G(s) is a transfer function of the HPF inserted.

In case the HPF is a first-order HPF, the transfer function G(s) is given by

$$G ( s ) = \frac{{K}_{1} {s}^{2}}{{s}^{2} + ( \frac{{ω}_{0}}{Q} ) s + {ω}_{0}^{2}} \qquad ( 63 )$$

A phase transfer function is further added. The phase error transfer function Hₑ(s) is defined by the following equation (64):

$${H}_{e} ( s ) ≡ \frac{{θ}_{e} ( s )}{{θ}_{i} ( s )} = \frac{s}{s + {K}_{d} {K}_{0} F ( s ) G ( s )} \qquad ( 64 )$$

In the present example, an RC first-order LPF is used as the loop filter 12. Therefore, in the case of the passive RC filter, shown in FIG. 14A, the transfer function F(s) is

$$F ( s ) = \frac{1}{1 + s τ} \qquad ( 65 )$$

where τ=RC.

In the case of an active RC filter, shown in FIG. 14B, its transfer function F(s) is

$$F ( s ) = {K}_{a} \frac{1}{1 + s τ} \qquad ( 66 )$$

where τ=RC and Ka=C₁/C₂.

In the case of the active inverting/integrating filter, shown in FIG. 14C, F(s) is given by

$$F ( s ) = \frac{1}{s τ} \qquad ( 67 )$$

where τ=RC.

In the case of the passive RC filter, shown in FIG. 14A, the closed loop transfer function H(s) of the PLL circuit is given by

$$\begin{matrix}\begin{matrix}H ( s ) = \frac{\frac{{K}_{d} {K}_{0} {K}_{1}}{τ} s}{\begin{matrix}{s}^{3} + \{ ( \frac{{ω}_{0}}{Q} ) + {ω}_{0}^{2} + \frac{1}{τ} \} {s}^{2} + \\ \{ \frac{1}{τ} ( \frac{{ω}_{0}}{Q} ) + \frac{{K}_{d} {K}_{0} {K}_{1}}{τ} \} s + \frac{{ω}_{0}^{2}}{τ} + {ω}_{0}^{2}\end{matrix}} \\ = \frac{( s + \frac{1}{τ} ) \frac{{K}_{d} {K}_{0} {K}_{1}}{τ} - \frac{{K}_{d} {K}_{0} {K}_{1}}{{τ}^{2}}}{( s + \frac{1}{τ} ) \{ {s}^{2} + ( \frac{{ω}_{0}}{Q} ) s + {ω}_{0}^{2} + \frac{{K}_{d} {K}_{0} {K}_{1}}{τ} \} - \frac{{K}_{d} {K}_{0} {K}_{1}}{{τ}^{2}}}\end{matrix} & ( 68 )\end{matrix}$$

There is included a term of s³ in the denominator of the equation (68), the order of s of which is higher than that in the quadratic equation of s. However, by setting K_{d}K₀K₁<<τ² the equation may be approximated by the following equation:

$$\begin{matrix}\begin{matrix}H ( s ) = \frac{( s + \frac{1}{τ} ) \frac{{K}_{d} {K}_{0} {K}_{1}}{τ} - \frac{{K}_{d} {K}_{0} {K}_{1}}{{τ}^{2}}}{( s + \frac{1}{τ} ) \{ {s}^{2} + ( \frac{{ω}_{0}}{Q} ) s + {ω}_{0}^{2} + \frac{{K}_{d} {K}_{0} {K}_{1}}{τ} \} - \frac{{K}_{d} {K}_{0} {K}_{1}}{{τ}^{2}}} \\ \approx \frac{\frac{{K}_{d} {K}_{0} {K}_{1}}{τ}}{{s}^{2} + ( \frac{{ω}_{0}}{Q} ) s + {ω}_{0}^{2} + \frac{{K}_{d} {K}_{0} {K}_{1}}{τ}} \\ = \frac{{ω}_{n}^{2} - {ω}_{0}^{2}}{{s}^{2} + 2 s {ξω}_{n} + {ω}_{n}^{2}}\end{matrix} & ( 69 )\end{matrix}$$

In similar manner, Hₑ(s) may be expressed by

$$\begin{matrix}{H}_{e} ( s ) = \frac{{s}^{3} + \{ ( \frac{{ω}_{0}}{Q} ) + {ω}_{0}^{2} + \frac{1}{τ} \} {s}^{2} + \frac{1}{τ} ( \frac{{ω}_{0}}{Q} ) s + \frac{{ω}_{0}^{2}}{τ} + {ω}_{0}^{2}}{\begin{matrix}{s}^{3} + \{ ( \frac{{ω}_{0}}{Q} ) + {ω}_{0}^{2} + \frac{1}{τ} \} {s}^{2} + \\ \{ \frac{1}{τ} ( \frac{{ω}_{0}}{Q} ) + \frac{{K}_{d} {K}_{0} {K}_{1}}{τ} \} s + \frac{{ω}_{0}^{2}}{τ} + {ω}_{0}^{2}\end{matrix}} \\ = \frac{( s + \frac{1}{τ} ) \{ {s}^{2} + ( \frac{{ω}_{0}}{Q} ) s + {ω}_{0}^{2} \}}{( s + \frac{1}{τ} ) \{ {s}^{2} + ( \frac{{ω}_{0}}{Q} ) s + {ω}_{0}^{2} + \frac{{K}_{d} {K}_{0} {K}_{1}}{τ} \} - \frac{{K}_{d} {K}_{0} {K}_{1}}{{τ}^{2}}}\end{matrix} \qquad ( 70 )$$

There is included a term of s₃ in the denominator of the equation (70), the order of s of which is higher than that of the quadratic equation of s. However, by setting K_{d}K₀K<<τ², the equation may be approximated by

$$\begin{matrix}{H}_{e} ( s ) = \frac{( s + \frac{1}{τ} ) \{ {s}^{2} + ( \frac{{ω}_{0}}{Q} ) s + {ω}_{0}^{2} \}}{( s + \frac{1}{τ} ) \{ {s}^{2} + ( \frac{{ω}_{0}}{Q} ) s + {ω}_{0}^{2} + \frac{{K}_{d} {K}_{0} {K}_{1}}{τ} \} - \frac{{K}_{d} {K}_{0} {K}_{1}}{{τ}^{2}}} \\ \approx \frac{{s}^{2} + ( \frac{{ω}_{0}}{Q} ) s + {ω}_{0}^{2}}{{s}^{2} + ( \frac{{ω}_{0}}{Q} ) s + {ω}_{0}^{2} + \frac{{K}_{d} {K}_{0} {K}_{1}}{τ}} \\ = \frac{{s}^{2} + 2 s {ξω}_{n} + {ω}_{0}^{2}}{{s}^{2} 2 s {ξω}_{n} + {ω}_{n}^{2}} \\ = 1 - H ( s )\end{matrix} \qquad ( 71 )$$

where ωₙ is a natural frequency represented by the equation (72)

$${ω}_{n} = \sqrt{\frac{{K}_{d} {K}_{0} {K}_{1} + {ω}_{0}}{τ}} \qquad ( 72 )$$

and ζ is a damping factor represented by the equation (73):

$$ξ = \frac{1}{2 {ω}_{n}} ( \frac{{ω}_{0}}{Q} ) \qquad ( 73 )$$

In the case of the active RC filter, shown in FIG. 14B, the closed loop transfer function H(s) of the PLL circuit is expressed as

$$H ( s ) = \frac{\frac{{K}_{d} {K}_{0} {K}_{1} {K}_{a}}{τ} s}{\begin{matrix}{s}^{3} + \{ ( \frac{{ω}_{0}}{Q} ) + {ω}_{0}^{2} + \frac{1}{τ} \} {s}^{2} + \\ \{ \frac{1}{τ} ( \frac{{ω}_{0}}{Q} ) + \frac{{K}_{d} {K}_{0} {K}_{1} {K}_{a}}{τ} \} s + \frac{{ω}_{0}^{2}}{τ} + {ω}_{0}^{2}\end{matrix}} = \frac{( s + \frac{1}{τ} ) \frac{{K}_{d} {K}_{0} {K}_{1} {K}_{a}}{τ} - \frac{{K}_{d} {K}_{0} {K}_{1} {K}_{a}}{{τ}^{2}}}{( s + \frac{1}{τ} ) \{ {s}^{2} + ( \frac{{ω}_{0}}{Q} ) s + {ω}_{0}^{2} + \frac{{K}_{d} {K}_{0} {K}_{1} {K}_{a}}{τ} \} - \frac{{K}_{d} {K}_{0} {K}_{1} {K}_{a}}{{τ}^{2}}} \qquad ( 74 )$$

There is included a term of s³ in the denominator of the equation (74), which therefore is higher in the order of s than the quadratic equation of s. However, by setting K_{d}K₀K₁Kₐ<<τ², the equation may be approximated by

$$H ( s ) = \frac{( s + \frac{1}{τ} ) \frac{{K}_{d} {K}_{0} {K}_{1} {K}_{a}}{τ} - \frac{{K}_{d} {K}_{0} {K}_{1} {K}_{a}}{{τ}^{2}}}{( s + \frac{1}{τ} ) \{ {s}^{2} + ( \frac{{ω}_{0}}{Q} ) s + {ω}_{0}^{2} + \frac{{K}_{d} {K}_{0} {K}_{1} {K}_{a}}{τ} \} - \frac{{K}_{d} {K}_{0} {K}_{1} {K}_{a}}{{τ}^{2}}} \approx \frac{\frac{{K}_{d} {K}_{0} {K}_{1} {K}_{a}}{τ}}{{s}^{2} + ( \frac{{ω}_{0}}{Q} ) s + {ω}_{0}^{2} + \frac{{K}_{d} {K}_{0} {K}_{1} {K}_{a}}{τ}} = \frac{{ω}_{n}^{2} - {ω}_{0}^{2}}{{s}^{2} + 2 s {ξω}_{n} + {ω}_{n}^{2}} \qquad ( 75 )$$

In similar manner, Hₑ(s) is expressed by

$${H}_{e} ( s ) = \frac{{s}^{3} + \{ ( \frac{{ω}_{0}}{Q} ) + {ω}_{0}^{2} + \frac{1}{τ} \} {s}^{2} + \frac{1}{τ} ( \frac{{ω}_{0}}{Q} ) s + \frac{{ω}_{0}^{2}}{τ} + {ω}_{0}^{2}}{\begin{matrix}{s}^{3} + \{ ( \frac{{ω}_{0}}{Q} ) + {ω}_{0}^{2} + \frac{1}{τ} \} {s}^{2} + \\ \{ \frac{1}{τ} ( \frac{{ω}_{0}}{Q} ) + \frac{{K}_{d} {K}_{0} {K}_{1} {K}_{a}}{τ} \} s + \frac{{ω}_{0}^{2}}{τ} + {ω}_{0}^{2}\end{matrix}} = \frac{( s + \frac{1}{τ} ) \{ {s}^{2} + ( \frac{{ω}_{0}}{Q} ) s + {ω}_{0}^{2} \}}{( s + \frac{1}{τ} ) \{ {s}^{2} + ( \frac{{ω}_{0}}{Q} ) s + {ω}_{0}^{2} + \frac{{K}_{d} {K}_{0} {K}_{1} {K}_{a}}{τ} \} - \frac{{K}_{d} {K}_{0} {K}_{1} {K}_{a}}{{τ}^{2}}} \qquad ( 76 )$$

There is included a term of s³ in the denominator of the equation (76), which therefore is higher in the order of s than the quadratic equation of s. However, by setting K_{d}K₀K₁Kₐ<<τ², the equation may be approximated by

$${H}_{e} ( s ) = \frac{( s + \frac{1}{τ} ) \{ {s}^{2} + ( \frac{{ω}_{0}}{Q} ) s + {ω}_{0}^{2} \}}{( s + \frac{1}{τ} ) \{ {s}^{2} + ( \frac{{ω}_{0}}{Q} ) s + {ω}_{0}^{2} + \frac{{K}_{d} {K}_{0} {K}_{1} {K}_{a}}{τ} \} - \frac{{K}_{d} {K}_{0} {K}_{1} {K}_{a}}{{τ}^{2}}} \approx \frac{{s}^{2} + ( \frac{{ω}_{0}}{Q} ) s + {ω}_{0}^{2}}{{s}^{2} + ( \frac{{ω}_{0}}{Q} ) s + {ω}_{0}^{2} + \frac{{K}_{d} {K}_{0} {K}_{1} {K}_{a}}{τ}} = \frac{{s}^{2} + 2 s {ξω}_{n} + {ω}_{0}^{2}}{{s}^{2} + 2 s {ξω}_{n} + {ω}_{n}^{2}} = 1 - H ( s ) \qquad ( 77 )$$

where ωₙ is a natural frequency represented by the equation (78)

$${ω}_{n} = \sqrt{\frac{{K}_{d} {K}_{0} {K}_{a} {K}_{1} + {ω}_{0}}{τ}} \qquad ( 78 )$$

and ζ is a damping factor represented by the equation (79)

$$ξ = \frac{1}{2 {ω}_{n}} ( \frac{{ω}_{0}}{Q} ) \qquad ( 79 )$$

In the case of the active inverting/integrating filter, shown in FIG. 14C, the closed-loop transfer function H(s) of the PLL circuit is given by

$$H ( s ) = \frac{\frac{{K}_{d} {K}_{0} {K}_{1}}{τ}}{{s}^{2} + ( \frac{{ω}_{0}}{Q} ) s + {ω}_{0}^{2} + \frac{{K}_{d} {K}_{0} {K}_{1}}{τ}} = \frac{{ω}_{n}^{2} - {ω}_{0}^{2}}{{s}^{2} + 2 s {ξω}_{n} + {ω}_{n}^{2}} \qquad ( 80 )$$

while Hₑ(s) is given by

$$\begin{matrix}{H}_{e} ( s ) = \frac{{s}^{2} + ( \frac{{ω}_{0}}{Q} ) s + {ω}_{0}^{2}}{{s}^{2} + ( \frac{{ω}_{0}}{Q} ) s + {ω}_{0}^{2} + \frac{{K}_{d} {K}_{0} {K}_{1}}{τ}} \\ = \frac{{s}^{2} + 2 s {ξω}_{n} + {ω}_{0}^{2}}{{s}^{2} + 2 s {ξω}_{n} + {ω}_{n}^{2}} \\ = 1 - H ( s )\end{matrix} \qquad ( 81 )$$

where ωₙ is a natural frequency represented by the equation (82)

$${ω}_{n} = \sqrt{\frac{{K}_{d} {K}_{0} {K}_{1}}{τ} + {ω}_{0}^{2}} \qquad ( 82 )$$

and ζ is a damping factor represented by the equation (83)

$$ξ = \frac{1}{2 {ω}_{n}} ( \frac{{ω}_{0}}{Q} ) \qquad ( 83 )$$

It should be noted that ωₙ and ζ are crucial parameters that govern the characteristic of the PLL circuit.

If K_{d}K₀>>ωₙ or K_{d}KₐK₀>>ωₙ, this PLL system is said to be a high gain loop. The most commonly used PLL has a high gain loop in order to improve tracking characteristic. Whether the PLL has a high gain loop or a low gain loop, ωₙ>>ω₀, and the time constant is of a large value, such that 1<<τ₁ and 1<<τ₁+τ₂. Hence, the equations (69), (75) and (80) may be expressed by the approximation (84):

$$H ( s ) \approx \frac{{ω}_{n}^{2}}{{s}^{2} + 2 s {ξω}_{n} + {ω}_{n}^{2}} \qquad ( 84 )$$

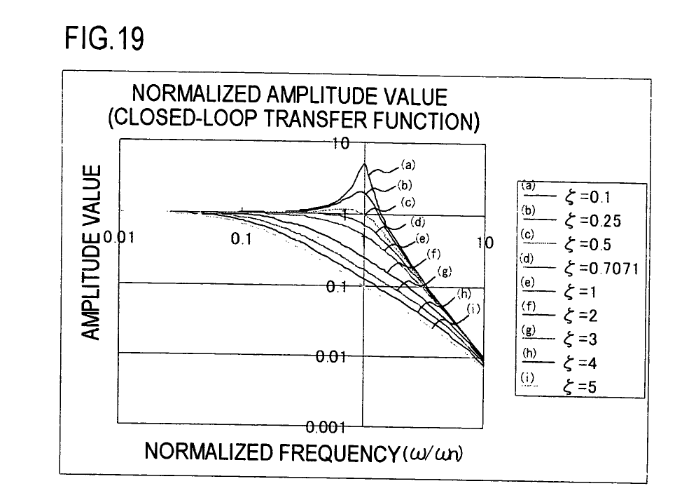

FIG. 19 shows amplitude characteristics of the closed-loop transfer function represented by the approximation (84) which is for the case of large values of the time constant of the equations (69), (75) and (80).

Also, whether the PLL has a high gain loop or a low gain loop, or whether a filter is a passive lag-lead filter, an active RC filter or an active inverting/integrating filter, the time constant is of a large value, such that ω₀<<τ. Hence, the phase error transfer function Hₑ(s), shown by the equation (71), (77) or (81), may be approximated by

$${H}_{e} ( s ) \approx \frac{{s}^{2} + 2 s {ξω}_{n}}{{s}^{2} + 2 s {ξω}_{n} + {ω}_{n}^{2}} \qquad ( 85 )$$

In the denominators of the phase error transfer functions Hₑ(s), shown by the equation (71), (77) or (81), or the approximation (85), there are contained terms of s other than the term s².

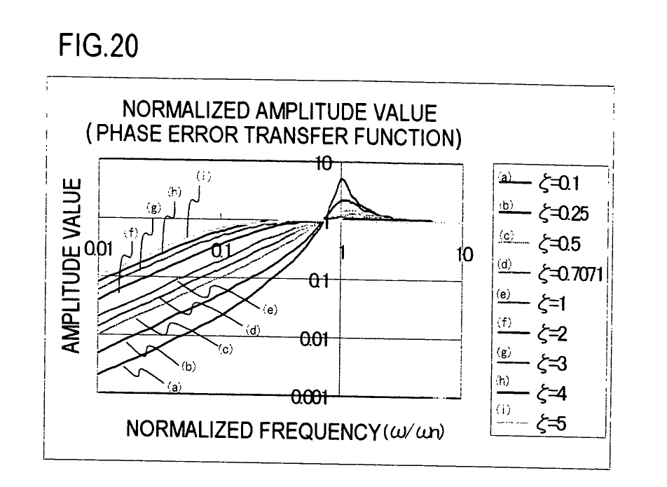

For reference sake, FIG. 20 shows amplitude characteristics of the approximation (85) which is for the phase error transfer function Hₑ(S). Even if the damping factor ζ is changed from 0.1 to 1, the amplitude values are all 1 for ω/ωₙ=1/√2. For ω/ωₙ>1/√2, the amplitude value becomes larger than 1, thus producing the overshooting.

The maximum value of the order of s in the denominator of the transfer function is 2, and hence the PLL is known as a second-order loop. In a well-known manner, the amplitude characteristic |H(jω)| of the loop transfer function H(jω), shown by the approximation (84), has the characteristic of a second-order LPF, while the amplitude characteristic |Hₑ(jω)| of the phase error transfer function Hₑ(jω), shown by the equation (85), has the characteristic of a second-order HPF characteristic.

Hence, the transfer function H(s) has a −3 dB cut-off frequency ω_{-3 dB}. It should be noticed that ω_{-3 dB} represents a closed loop band of the PLL circuit. If, in the high gain loop, the amplitude characteristic |Hₑ(jω)| is set so that

$$\vert H ( jω ) \vert = \frac{1}{\sqrt{2}}$$

and the transfer function is solved for ω, there may be obtained

$$\begin{matrix}{ω}_{- 3 dB} = {ω}_{n} \sqrt{1 - 2 {ξ}^{2} + \sqrt{1 + {( 2 {ξ}^{3} - 1 )}^{2}}} \\ = {ω}_{n} \sqrt{1 - 2 {ξ}^{2} + \sqrt{4 {ξ}^{4} - 4 {ξ}^{2} + 2}}\end{matrix} \qquad ( 86 )$$

Noteworthy is the fact that the closed loop transfer function, expressed by the approximation (84), is the transfer function of the second-order LPF itself, while the phase error transfer function, defined by the approximation (85), is of the characteristic close to that of the second-order HPF. This relationship is the reverse of that of the case of the PLL circuit that makes use of the conventional VCO.

### THIRD EXAMPLE

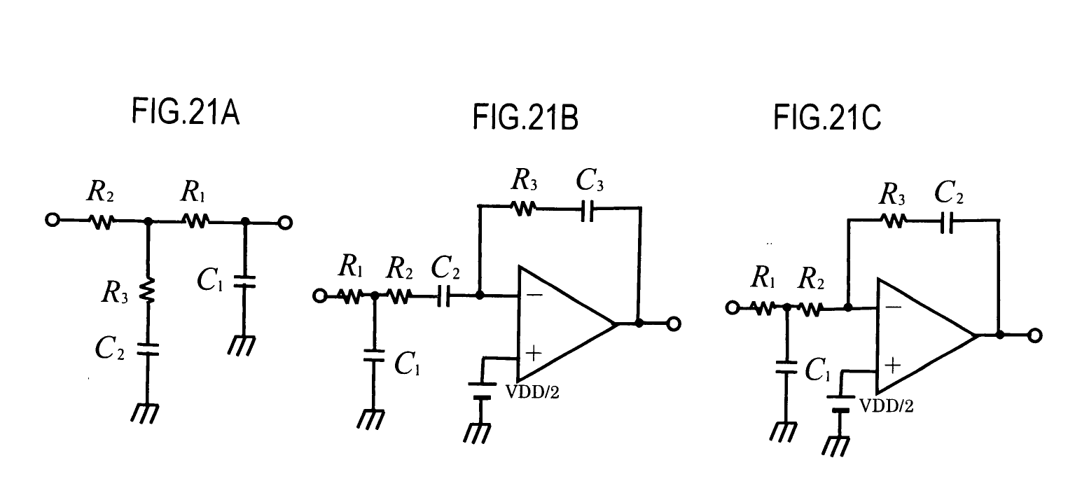

In the above-described first and second examples, a first-order LPF is used as a loop filter. However, since there is still the phase margin of 90° as the PLL loop, the first-order LPF may be replaced by a cascaded connection of a first-order LPF and a lag-lead filter. FIGS. 21A to 21C show examples of the loop filter used in this case.

The transfer function for FIG. 21A is such that

$$\begin{matrix}{F}_{1} ( s ) = \frac{1}{1 + s {τ}_{1}} & ( 87 ) \\ {F}_{2} ( s ) = \frac{1 + s {τ}_{3}}{1 + s ( {τ}_{2} + {τ}_{3} )} \\ and & ( 88 ) \\ F ( s ) = {F}_{1} ( s ) \cdot {F}_{2} ( s ) = \frac{1}{1 + s {τ}_{1}} \frac{1 + s {τ}_{3}}{1 + s ( {τ}_{2} + {τ}_{3} )} & ( 89 )\end{matrix}$$

where τ₁=R₁C₁, τ₂=R₂C₂ and τ₃=R₃C₂.

For simplification, set τ₁=τ₃. Then,

$$F ( s ) = \frac{1}{1 + s ( {τ}_{2} + {τ}_{3} )} = \frac{1}{1 + s {τ}_{0}} \qquad ( 90 )$$

where τ₀=τ₁+τ₃.

The equation (90) represents a case equivalent to using an RC first-order LPF for the loop filter in the first and second examples and setting τ₀ for τ in its transfer function F(s).

Similarly, the transfer function for FIG. 21B is such that

$$\begin{matrix}{F}_{1} ( s ) = \frac{1}{1 + s {τ}_{1}} & ( 91 ) \\ {F}_{2} ( s ) = {K}_{a} \frac{1 + s {τ}_{3}}{1 + s {τ}_{2}} \\ and & ( 92 ) \\ F ( s ) = {F}_{1} ( s ) \cdot {F}_{2} ( s ) = {K}_{a} \frac{1}{1 + s {τ}_{1}} \frac{1 + s {τ}_{3}}{1 + s {τ}_{2}} & ( 93 )\end{matrix}$$

where τ₁=R₁C₁, τ₂=R₂C₂, τ₃=R₃C₂ and Kₐ=C₂/C₃.

For simplification, set τ₁=τ₃. Then,

$$F ( s ) = \frac{1}{1 + s {τ}_{2}} = \frac{1}{1 + s {τ}_{0}} \qquad ( 94 )$$

where τ₀=τ₂.

The equation (94) represents a case equivalent to using an RC first-order LPF for the loop filter 12 in the first and second examples (see FIGS. 12 and 17) and setting τ₀ for τ in its transfer function F(s).

Similarly, the transfer function for FIG. 21C is such that

$$\begin{matrix}{F}_{1} ( s ) = \frac{1}{1 + s {τ}_{1}} & ( 95 ) \\ {F}_{2} ( s ) = \frac{1 + s {τ}_{3}}{s {τ}_{2}} \\ and & ( 96 ) \\ F ( s ) = {F}_{1} ( s ) \cdot {F}_{2} ( s ) = {K}_{a} \frac{1}{1 + s {τ}_{1}} \frac{1 + s {τ}_{3}}{s {τ}_{2}} & ( 97 )\end{matrix}$$

where τ₁=R₁C₁, τ₂=R₂C₂ and τ₃=R₃C₂.

For simplification, set τ₁=τ₃. Then,

$$F ( s ) = \frac{1}{s {τ}_{2}} = \frac{1}{s {τ}_{0}} \qquad ( 98 )$$

where τ0=τ2.

The equation (98) represents a case equivalent to using an RC first-order LPF for the loop filter in the first and second examples and setting τ₀ for τ in its transfer function F(s).

Thus, in the above-described first and second examples, a cascaded connection of the first-order LPF and the lag-lead filter may be used as the loop filter 12.

As a method for advancing the phase in the PLL loop, a method of introducing a first-order HPF or a second-order HPF into the loop has been described above in detail.

However, the present invention is not restricted to the above-described method. Since an input signal to the phase detector (PD) may be a rectangular wave, the phase lead equivalent to up to −180° may be achieved by forming the VCO output into a rectangular wave, inverting it and delaying the resulting signal by a delay circuit.

### FOURTH EXAMPLE

FIG. 22 shows the configuration of a PLL circuit of a fourth example of the present invention. With the PLL circuit, shown in FIG. 22, an output of the VCO 13 is formed into a rectangular wavelength by a single-stage inverter 16, and the resulting rectangular signal is further delayed by a delay circuit 17. This processing is equivalent to advancing the phase by up to −180°.

Referring to FIG. 22, a single-stage inverter circuit 16 is connected to an output of the VCO 13. An output signal of the inverter circuit 16 is supplied to the delay circuit 17 where the phase of the rectangular signal is delayed. A signal from the delay circuit 17 (rectangular signal) and the input signal are supplied to a phase detector (PD) 11. An output of the phase detector (PD) 11 is supplied to a loop filter 12 where the AC component is eliminated. The DC component is delivered as a control signal to the VCO 13.

The PLL circuit, shown in FIG. 22, is operated even with the rectangular input signal to the phase detector (PD) 11. Hence, the output of the VCO 13 is formed into a rectangular waveform via the single-stage inverter 16, and the resulting rectangular signal is delayed by the delay circuit 17.

This processing is equivalent to advancing the phase by up to −180°. The delay caused by the newly inserted delay circuit 17 corresponds to the phase margin.

Hence, the delay set in the delay circuit 17 must not exceed 180° in terms of the phase. The delay D is expressed by a differential coefficient of the phase θ with respect to the angular velocity ω:

$$D = \frac{- d θ}{d ω} \qquad ( 99 )$$

In the example shown in FIG. 22, a delay circuit 17 is provided in rear of the inverter circuit 16. However, the order of the circuit elements may be reversed, that is, the inverter circuit may be provided in rear of the delay circuit.

Or, the inverter 16 may also be an inverting amplifier. In case the delay circuit is provided ahead of the inverter 16, the delay circuit may not be a digital circuit and may be an analog circuit.

There are a number of related art techniques of the digital delay circuit, such as one making use of flip-flops. The related art techniques of the analog delay circuits are described in great detail in Non-Patent Document 3 (K. Bult and H. W. Walling a, “A CMOS Analog Continuous-Time Delay Line with Adaptive Delay-Time Control”, IEEE J. Solid-State Circuits, Vol. SC-23, No. 3, pp. 759-766, June 1988).

### OTHER EXAMPLES OF THE INVENTION

In the PLL circuit of each of the first to fourth examples, described above, a frequency divider may be inserted on an input side of the phase detector (PD) to lower the frequency of the input signal.

### FIFTH EXAMPLE

The configuration of a fifth example of the present invention is shown in FIG. 23. When a frequency divider 18 is provided in the PLL circuit, employing the VCO of the present invention, the resulting circuit is as shown in FIG. 23. In FIG. 23, a 1/n frequency divider 18 is provided in rear of a first-order HPF 14 or a second-order HPF 15, provided on an output side of a VCO 13, for frequency dividing the frequency signal output from the VCO 13. This frequency divided signal is to be one of two input signals to a phase detector (PD) 11. Hence, the frequency of the other input signal to the phase detector (PD) 11 may be lowered to 1/n.

### SIXTH EXAMPLE

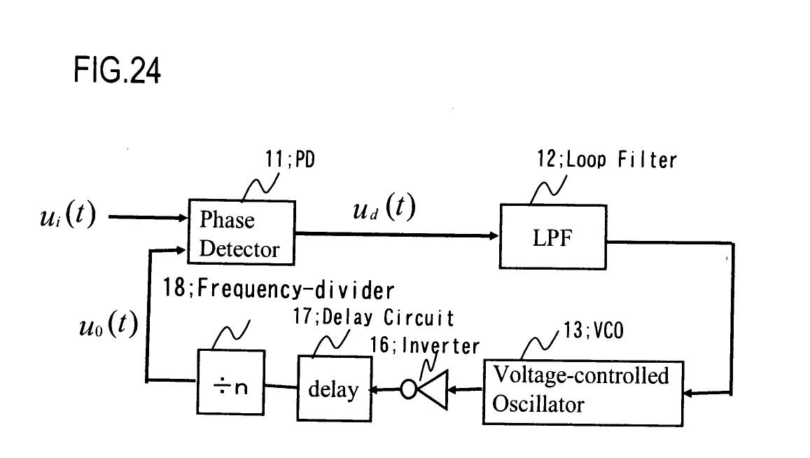

The configuration of a sixth example of the present invention is shown in FIG. 24. When a frequency divider 18 is provided in the PLL circuit, employing the VCO of the present invention, shown in FIG. 22, the resulting circuit is as shown in FIG. 24. In FIG. 24, a 1/n frequency divider 18 is provided in rear of an inverter 16 and a delay circuit 17, provided on an output of the VCO 13, for frequency dividing the frequency signal output from the VCO 13 to 1/n. This frequency divided signal is to be one of two input signals to a phase detector (PD) 11. Hence, the frequency of the other input signal to the phase detector (PD) 11 may be lowered to 1/n.

In FIG. 24, the delay circuit 17 and the frequency divider 18 are inserted in this order in rear of the inverter 16. However, the order of arraying the delay circuit, inverter and the frequency divider may be set arbitrarily. The inverter may be an inverting amplifier. In case the delay circuit is inserted ahead of the inverter, the delay circuit may not be a digital circuit and may also be an analog circuit.

The PLL circuit employing the VCO of the present invention has been described above. The following description is relative with a tuning system for a gm-C filter as an example of the application of the PLL circuit that makes use of the VCO according to the present invention. This related art technique has been described in great detail in Non-Patent Document 1 (F. Krummenacher and N. Joehl, “A 4-MHz CMOS Continuous-Time Filters with On-Chip Automatic Tuning”, IEEE J. Solid-State Circuits, Vol. SC-23, No. 3, pp. 750-758, June 1988).

In like manner, the lag-lead filter of the loop filter may be changed to an RC filter by using an HPF in a PLL circuit that makes use of a filter (VCF) in place of the VCO circuit.

### SEVENTH EXAMPLE

In the seventh example, shown in FIG. 25, a first-order HPF 23 is used as a filter circuit in the PLL employing a VCF circuit.

In the first-order HPF 23, the phase advances by 90°, so that, in a PLL loop, the sole phase delay is that caused in the loop filter 22.

Thus, if the first-order LPF (RC filter) 23 is used as the loop filter 22, and the phase delay of 90° is produced, the phase delay may be in a range from −180° to 180°. That is, there is no necessity to use the lag-lead filter.

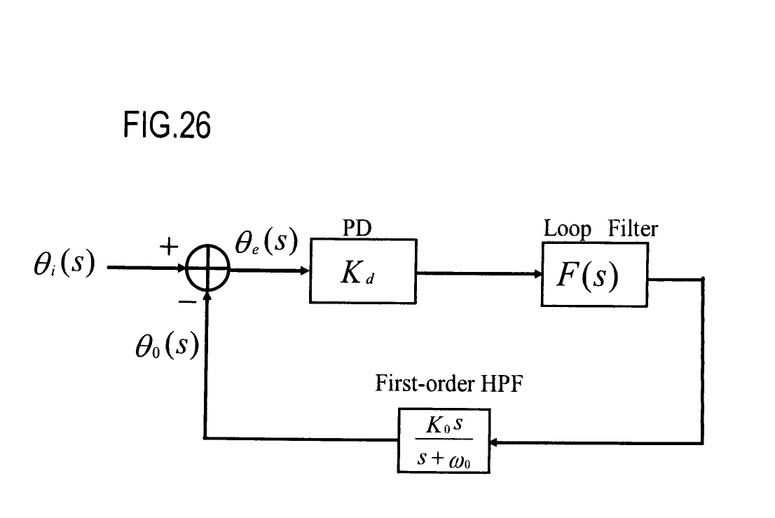

The PLL circuit, shown in FIG. 25, may be revised to a linear PLL circuit model shown in FIG. 26.

In FIG. 25, a reference frequency φᵢₙ(t) and an output φₒᵤₜ(t) of the first-order HPF (VCF) 23 are supplied to a phase detector 21. An output of the phase detector 21 is supplied to the loop filter 22 where the AC component is eliminated and the DC component is delivered as a control voltage to the first-order HPF (VCF) 23.

Referring to FIG. 25, the reference frequency φᵢₙ(t) and the output φₒᵤₜ(t) of the first-order HPF (VCF) 23 are supplied to the phase detector 21, where the phase difference between them is detected.

Both the reference frequency φᵢₙ(t) and the output φₒᵤₜ(t) of the first-order HPF (VCF) 23 are contained in an output signal of the phase detector 21. This output signal is delivered as a phase error signal to the loop filter 22 where the AC component is eliminated. The DC component is delivered as control signal to the first-order HPF (VCF) 23, which then exercises control to provide a constant phase difference between the output of the first-order HPF (VCF) 23 and the reference frequency.

The PLL circuit, shown in FIG. 25, may be revised to a linear PLL circuit model shown in FIG. 26. In FIG. 26, the closed-loop transfer function of the PLL circuit may be defined, based on the control theory, by the following equation (100):

$$H ( s ) ≡ \frac{{θ}_{0} ( s )}{{θ}_{i} ( s )} = \frac{{K}_{d} F ( s ) G ( s )}{1 + {K}_{d} F ( s ) G ( s )} \qquad ( 100 )$$

In the above equation,

Kd[V/rad] is the gain of a phase detector (PD),

F(s) is a transfer function of a loop filter (LP),

K₀[rad/s-V] is a gain factor of the VCO, and

G(s) is a transfer function of the HPF inserted.

Since the first-order HPF is used in the present example as the VCF, the transfer function of G(s) is given by

$$G ( s ) = \frac{{K}_{1} s}{s + {ω}_{0}} \qquad ( 101 )$$

A phase transfer function is further added. The phase error transfer function Hₑ(s) is defined by the following equation (102):

$${H}_{e} ( s ) ≡ \frac{{θ}_{e} ( s )}{{θ}_{i} ( s )} = \frac{1}{1 + {K}_{d} F ( s ) G ( s )} \qquad ( 102 )$$

In the present example, an RC first-order LPF is used as the loop filter 22. Thus, in the case of the passive RC filter, shown in FIG. 14A, its transfer function F(s) is

$$F ( s ) = \frac{1}{1 + s τ} \qquad ( 103 )$$

where τ=RC.

In case the loop filter 22 is the active RC filter, shown in FIG. 14B, its transfer function F(s) is given by

$$F ( s ) = {K}_{a} \frac{1}{1 + s τ} \qquad ( 104 )$$

where τ=RC₁ and Kₐ=C₁/C₂.

In case the loop filter 22 is the active inverting/integrating filter, shown in FIG. 14C, its transfer function F(s) is

$$F ( s ) = \frac{1}{s τ} \qquad ( 105 )$$

where τ=RC.

In case the loop filter 22 is the passive RC filter, shown in FIG. 14A, the closed-loop transfer function of the PLL circuit H(s) is

$$H ( s ) = \frac{\frac{{K}_{d} {K}_{1}}{τ} s}{{s}^{2} + ( \frac{1}{τ} + {ω}_{0} + \frac{{K}_{d} {K}_{1}}{τ} ) s + \frac{{ω}_{0}}{τ}} = \frac{( 2 {ξω}_{n} - \frac{1}{τ} - {ω}_{0} ) s}{{s}^{2} + 2 s {ξω}_{n} + {ω}_{n}^{2}} \qquad ( 106 )$$

The phase error transfer function Hₑ(S) is

$$\begin{matrix}{H}_{e} ( s ) = \frac{{s}^{2} + ( \frac{1}{τ} + {ω}_{0} ) s + \frac{{ω}_{0}}{τ}}{{s}^{2} + ( \frac{1}{τ} + {ω}_{0} + \frac{{K}_{d} {K}_{1}}{τ} ) s + \frac{{ω}_{0}}{τ}} \\ = \frac{{s}^{2} + ( 2 {ξω}_{n} - \frac{{K}_{d} {K}_{1}}{τ} ) s + \frac{{ω}_{0}}{τ}}{{s}^{2} + 2 s {ξω}_{n} + {ω}_{n}^{2}} \\ = 1 - H ( s )\end{matrix} \qquad ( 107 )$$

where ωₙ denotes the natural frequency represented by the equations (108):

$${ω}_{n} = \sqrt{\frac{{ω}_{0}}{τ}} \qquad ( 108 )$$

and ζ denotes the damping factor represented by the equation (109):

$$ξ = \frac{{ω}_{n}}{2} ( \frac{1}{{ω}_{0}} + τ + \frac{{K}_{d} {K}_{1}}{{ω}_{0}} ) \qquad ( 109 )$$

In case the loop filter 22 is an active RC filter, shown in FIG. 14B, the closed-loop transfer function of the PLL circuit H(s) is

$$H ( s ) = \frac{\frac{{K}_{d} {K}_{a} {K}_{1}}{τ}}{{s}^{2} + s ( \frac{1}{τ} + {ω}_{0} ) + \frac{{K}_{d} {K}_{a} {K}_{1} + {ω}_{0}}{τ}} = \frac{{ω}_{n}^{2} - \frac{{ω}_{0}}{τ}}{{s}^{2} + 2 s ξ {ω}_{n} + {ω}_{n}^{2}} \qquad ( 110 )$$

The phase error transfer function Hₑ(s) is

$${H}_{e} ( s ) = \frac{{s}^{2} + s ( \frac{1}{τ} + {ω}_{0} ) + \frac{{ω}_{0}}{τ}}{{s}^{2} + s ( \frac{1}{τ} + {ω}_{0} ) + \frac{{K}_{d} {K}_{a} {K}_{1} + {ω}_{0}}{τ}} = \frac{{s}^{2} + 2 s {ξω}_{n} + \frac{{ω}_{0}}{τ}}{{s}^{2} + 2 s ξ {ω}_{n} + {ω}_{n}^{2}} = 1 - H ( s ) \qquad ( 111 )$$

where ωₙ and ζ respectively denote the natural frequency represented by the equations (112):

$${ω}_{n} = \sqrt{\frac{{K}_{d} {K}_{a} {K}_{1} + {ω}_{0}}{τ}} \qquad ( 112 )$$

and the damping factor represented by the equation (113):

$$ξ = \frac{{ω}_{n}}{2} ( \frac{1}{τ} + {ω}_{0} ) \qquad ( 113 )$$

In case the loop filter 22 is an active inverting/integrating filter, shown in FIG. 14C, the closed-loop transfer function of the PLL circuit H(s) is

$$H ( s ) = \frac{\frac{{K}_{d} {K}_{1}}{τ}}{{s}^{2} + {ω}_{0} s + \frac{{K}_{d} {K}_{1}}{τ}} = \frac{{ω}_{n}^{2}}{{s}^{2} + 2 s ξ {ω}_{n} + {ω}_{n}^{2}} \qquad ( 114 )$$

The phase error transfer function Hₑ(s) is

$${H}_{e} ( s ) = \frac{{s}^{2} + {ω}_{0} s}{{s}^{2} + {ω}_{0} s + \frac{{K}_{d} {K}_{1}}{τ}} = \frac{{s}^{2} + 2 s ξ {ω}_{n}}{{s}^{2} + 2 s ξ {ω}_{n} + {ω}_{n}^{2}} = 1 - H ( s ) \qquad ( 115 )$$

where ωₙ and ζ respectively denote the natural frequency represented by the equations (116):

$${ω}_{n} = \sqrt{\frac{{K}_{d} {K}_{1}}{τ}} \qquad ( 116 )$$

and the damping factor represented by the equation (117):

$$ξ = \frac{{ω}_{n}}{2} ( \frac{{ω}_{0} τ}{{K}_{d} {K}_{1}} ) \qquad ( 117 )$$

It should be noticed that ωₙ and ζ are crucial parameters that govern the characteristics of the PLL circuit.

If K_{d}K₀>>ωₙ or K_{d}KₐK₀>>ωₙ, this PLL system is said to be a high gain loop. The most commonly used PLL has a high gain loop in order to improve tracking characteristic.

Whether the PLL has a high gain loop or a low gain loop, ωₙ>>ω₀, and the time constant is of a large value, such that <<τ₁. Hence, the equations (106) and (110) may be approximated by the equation (114), and represented by the following approximation:

$$H ( s ) \approx \frac{{ω}_{n}^{2}}{{s}^{2} + 2 s ξ {ω}_{n} + {ω}_{n}^{2}} \qquad ( 118 )$$

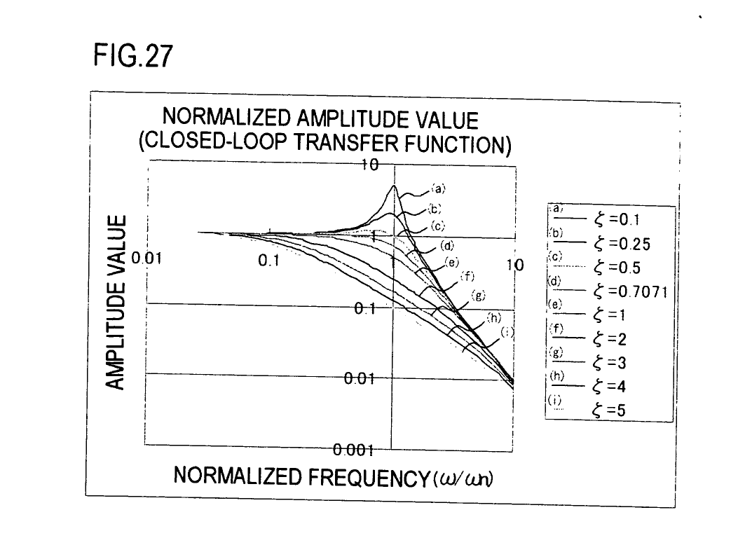

FIG. 27 shows amplitude characteristics of the closed-loop transfer function represented by the approximation (118), which is for the case of the large value of the time constant of the equations (106) and (110), and the closed-loop transfer function represented by the equation (114).

Also, whether the PLL has a high gain loop or a low gain loop, or whether a filter is a passive lag RC filter, an active RC filter or an active inverting/integrating filter, the time constant is of a large value, such that K_{d}K₁<<τ and ω₀<<τ. Hence, the equations (107), (111) may be approximated to the phase error transfer function Hₑ(S), shown by the equation (115), and may be represented by the following approximation:

$${H}_{e} ( s ) \approx \frac{{s}^{2} + 2 s ξ {ω}_{n}}{{s}^{2} + 2 s ξ {ω}_{n} + {ω}_{n}^{2}} \qquad ( 119 )$$

In the denominators of the phase error transfer functions Hₑ(s), shown by the equation (107), (111) or (115), or the approximation (119), there are contained terms of s other than the term s².

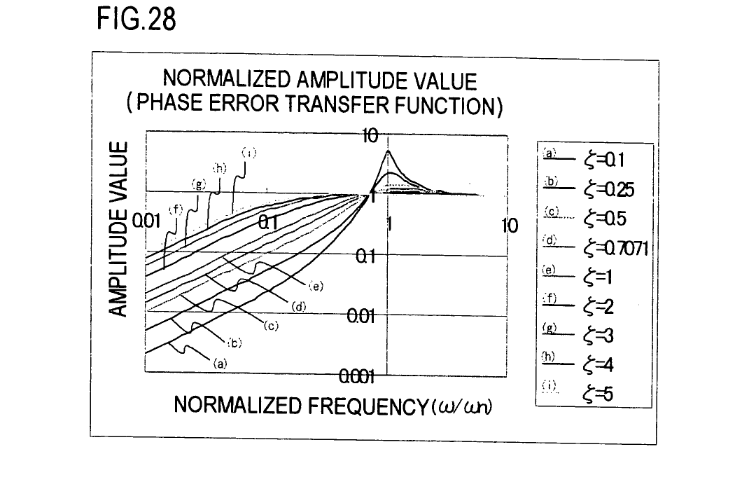

For reference sake, FIG. 28 shows amplitude characteristics of the approximation (119) which is to take the place of the phase error transfer function Hₑ(s). Even if the damping factor ζ is changed from 0.1 to 1, the amplitude values are all 1 for ω/ωₙ=1/√2. For ω/ωₙ>1/√2, the amplitude value becomes larger than 1, thus causing the overshooting.

The maximum value of the order of s in the denominator of the transfer function is 2, and hence the PLL is known as a second-order loop. In a well-known manner, the amplitude characteristic |H(jω)| of the loop transfer function H(jω), shown by the approximation (118), is the characteristic of a second-order LPF, while the amplitude characteristic |Hₑ(jω)| of the phase error transfer function Hₑ(jω), shown by the approximation (119), is the characteristic of a second-order HPF.

Hence, the transfer function H(s) has a −3 dB cut-off frequency ω_{-3 dB}. It should be noticed that ω_{-3 dB} represents a closed loop band of the PLL circuit. If, in the high gain loop, the amplitude characteristic |Hₑ(jω)| is set so that

$$\vert H ( j ω ) \vert = \frac{1}{\sqrt{2}}$$

and the transfer function is solved for ω, there may be obtained

$${ω}_{- 3 dB} = {ω}_{n} \sqrt{1 - 2 {ξ}^{2} + \sqrt{1 + {( 2 {ξ}^{2} - 1 )}^{2}}} = {ω}_{n} \sqrt{1 - 2 {ξ}^{2} + \sqrt{4 {ξ}^{4} - 4 {ξ}^{2} + 2}} \qquad ( 120 )$$

Noteworthy is the fact that the closed loop transfer function, shown by the approximation (118), is the transfer function of the second-order LPF itself, while the phase error transfer function defined by the approximation (119) is of the characteristic close to the second-order HPF characteristic. This relationship is the reverse of that of the case of the PLL circuit that makes use of the conventional VCO.

It may further be remarked that, with the conventional PLL circuit, making use of the VCO, the term of s is included in the denominator of the phase error transfer function. Thus, it may sometimes occur that fluctuations may be produced in the stop band area such that the amplitude characteristic of the phase error transfer function is closer to that shown in FIG. 28 than that shown in FIG. 5.

As for the value of the damping factor ζ, ζ=0.7071 (=1/√2) in the case of the PLL circuit that makes use of the conventional VCO. If, with the PLL circuit, making use of the VCO of the present example, ζ is set to ζ=5, the error of the control voltage is comprised within ±1% or less in case ω/ωₙ exceeds 0.6.

However, even if the damping factor ζ is set to a larger value, the maximum value of the control voltage exceeds a preset value, to a more or less extent, without assuming a value smaller than the preset value. That is, with the PLL circuit, making use of the VCO of the present invention, it is not proper to define ζ as a damping factor in the hitherto accepted sense of the term.

### EIGHTH EXAMPLE

In order to maintain the negative feedback loop, it is sufficient that the phase range is intermediate between −180° and 180°. It may therefore be contemplated to take advantage of the phase range of −180° to 0° and to insert a second-order LPF on an output side of the VCO. Since the signal phase would be offset only in the delaying direction, due to e.g. the parasitic capacitance, the phase margin for −180° may presumably be maintained even if the second-order HPF is inserted.

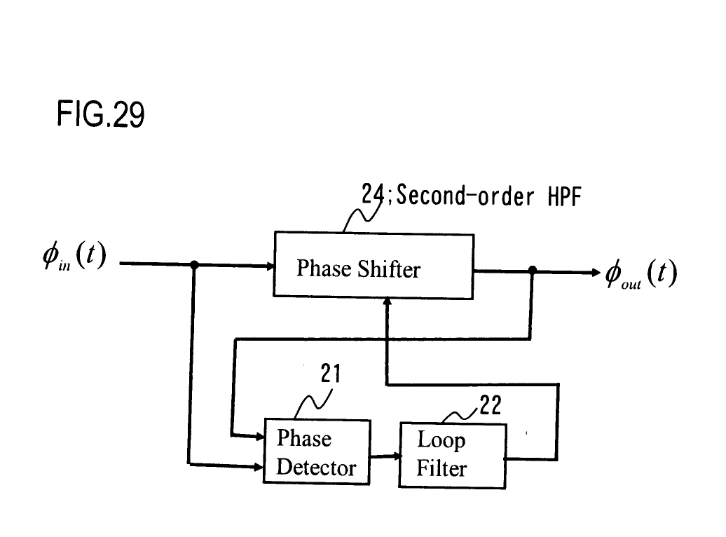

FIG. 29 shows the configuration of a PLL circuit, including a second-order HPF 24 inserted at an output side of the VCO 13, by way of an eighth example of the present invention.

Referring to FIG. 29, a reference frequency φᵢₙ(t) and an output φₒᵤₜ(t) of the second-order HPF 24 are supplied to a phase detector 21. An output of the phase detector 21 is supplied to a loop filter 22 where the AC component is removed so that the DC component is supplied as a control voltage to the VCO. An output of the loop filter 22 is supplied to the second-order HPF 24 which then delivers φₒᵤₜ(t) as output signal.

Referring to FIG. 29, the reference frequency φₒᵤₜ(t) and the output signal φₒᵤₜ(t) of the second-order HPF 24 are supplied to the phase detector 21, where the phase difference between the two is detected. In an output signal of the phase detector 21, there are contained, a DC component, as a phase error signal, and an AC component. The output signal is supplied to the loop filter 22 where the AC component is eliminated and only the DC component is supplied to the second-order HPF 24. This second-order HPF delivers the output signal φₒᵤₜ(t) having a phase lead of 180°.

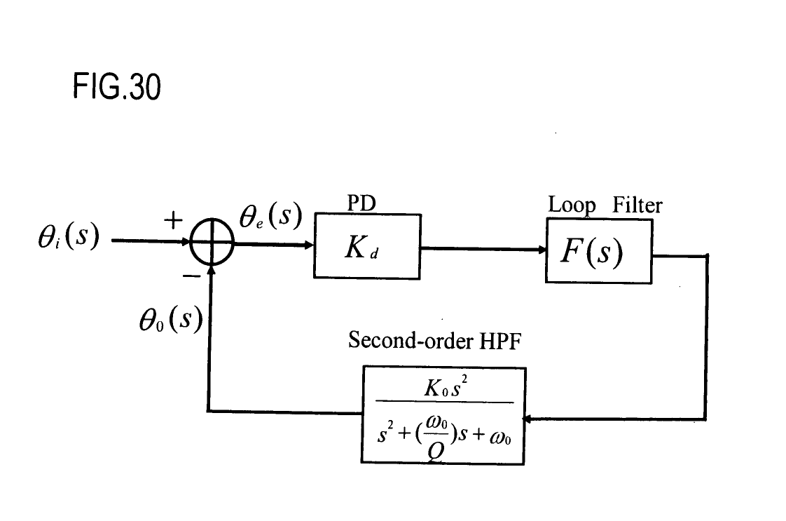

The PLL circuit, shown in FIG. 29, may be revised to a linear PLL circuit model shown in FIG. 30. In FIG. 30, the closed-loop transfer function of the PLL circuit may be defined, based on the control theory, by the following equation (121):

$$H ( s ) ≡ \frac{{θ}_{0} ( s )}{{θ}_{1} ( s )} = \frac{{K}_{d} {K}_{0} F ( s ) G ( s )}{s + {K}_{d} {K}_{0} F ( s ) G ( s )} \qquad ( 121 )$$

In the above equation,

Kd[V/rad] is the gain of the phase detector (PD),

F(s) is a transfer function of the loop filter (LP),

K₀[rad/s-V] is a gain factor of the VCO, and

G(s) is a transfer function of the HPF 24 inserted.

Since the second-order HPF is used in the present example, as the HPF inserted, the transfer function G(s) is defined as

$$G ( s ) = \frac{{K}_{1} {s}^{2}}{{s}^{2} + ( \frac{{ω}_{0}}{Q} ) s + {ω}_{0}^{2}} \qquad ( 122 )$$

A phase transfer function is further added. The phase error transfer function Hₑ(s) is defined by the following equation (123):

$${H}_{e} ( s ) ≡ \frac{{θ}_{e} ( s )}{{θ}_{i} ( s )} = \frac{s}{s + {K}_{d} {K}_{0} F ( s ) G ( s )} \qquad ( 123 )$$

In the present example, an RC first-order LPF is used as the loop filter 22. Hence, in the case of the passive RC filter, shown in FIG. 14A, the transfer function F(s) is

$$F ( s ) = \frac{1}{1 + s τ} \qquad ( 124 )$$

where τ=RC.

In case the loop filter 22 is the active RC filter, shown in FIG. 14B, its transfer function F(s) is given by

$$F ( s ) = {K}_{a} \frac{1}{1 + s τ} \qquad ( 125 )$$

where τ=RC, and Kₐ=C₁/C₂.

In case the loop filter 22 is the active inverting/integrating filter, shown in FIG. 14C, its transfer function F(s) is

$$F ( s ) = \frac{1}{s τ} \qquad ( 126 )$$

where τ=RC.

In case the loop filter 22 is the passive RC filter, shown in FIG. 14A, the closed-loop transfer function of the PLL circuit H(s) is

$$\begin{matrix}H ( s ) = \frac{\frac{{K}_{d} {K}_{0} {K}_{1}}{τ} s}{\begin{matrix}{s}^{3} + \{ ( \frac{{ω}_{0}}{Q} ) + {ω}_{0}^{2} + \frac{1}{τ} \} {s}^{2} + \\ \{ \frac{1}{τ} ( \frac{{ω}_{0}}{Q} ) + \frac{{K}_{d} {K}_{0} {K}_{1}}{τ} \} s + \frac{{ω}_{0}^{2}}{τ} + {ω}_{0}^{2}\end{matrix}} \\ = \frac{( s + \frac{1}{τ} ) \frac{{K}_{d} {K}_{0} {K}_{1}}{τ} - \frac{{K}_{d} {K}_{0} {K}_{1}}{{τ}^{2}}}{( s + \frac{1}{τ} ) \{ {s}^{2} + ( \frac{{ω}_{0}}{Q} ) s + {ω}_{0}^{2} + \frac{{K}_{d} {K}_{0} {K}_{1}}{τ} \} - \frac{{K}_{d} {K}_{0} {K}_{1}}{{τ}^{2}}}\end{matrix} \qquad ( 127 )$$

There is included a term of s³ in the denominator of the equation (127), which therefore is higher in the order of s than the quadratic equation of s. However, by setting K_{d}K₀K₁<<τ², the equation may be approximated by

$$\begin{matrix}H ( s ) = \frac{( s + \frac{1}{τ} ) \frac{{K}_{d} {K}_{0} {K}_{1}}{τ} - \frac{{K}_{d} {K}_{0} {K}_{1}}{{τ}^{2}}}{( s + \frac{1}{τ} ) \{ {s}^{2} + ( \frac{{ω}_{0}}{Q} ) s + {ω}_{0}^{2} + \frac{{K}_{d} {K}_{0} {K}_{1}}{τ} \} - \frac{{K}_{d} {K}_{0} {K}_{1}}{{τ}^{2}}} \\ \approx \frac{\frac{{K}_{d} {K}_{0} {K}_{1}}{τ}}{{s}^{2} + ( \frac{{ω}_{0}}{Q} ) s + {ω}_{0}^{2} + \frac{{K}_{d} {K}_{0} {K}_{1}}{τ}} \\ = \frac{{ω}_{n}^{2} - {ω}_{0}^{2}}{{s}^{2} + 2 s {ξω}_{n} + {ω}_{n}^{2}}\end{matrix} \qquad ( 128 )$$

In like manner, the phase error transfer function Hₑ(s) is

$$\begin{matrix}{H}_{e} ( s ) = \frac{{s}^{3} + \{ ( \frac{{ω}_{0}}{Q} ) + {ω}_{0}^{2} + \frac{1}{τ} \} {s}^{2} + \frac{1}{τ} ( \frac{{ω}_{0}}{Q} ) s + \frac{{ω}_{0}^{2}}{τ} + {ω}_{0}^{2}}{\begin{matrix}{s}^{3} + \{ ( \frac{{ω}_{0}}{Q} ) + {ω}_{0}^{2} + \frac{1}{τ} \} {s}^{2} + \\ \{ \frac{1}{τ} ( \frac{{ω}_{0}}{Q} ) + \frac{{K}_{d} {K}_{0} {K}_{1}}{τ} \} s + \frac{{ω}_{0}^{2}}{τ} + {ω}_{0}^{2}\end{matrix}} \\ = \frac{( s + \frac{1}{τ} ) \{ {s}^{2} + ( \frac{{ω}_{0}}{Q} ) s + {ω}_{0}^{3} \}}{( s + \frac{1}{τ} ) \{ {s}^{2} + ( \frac{{ω}_{0}}{Q} ) s + {ω}_{0}^{2} + \frac{{K}_{d} {K}_{0} {K}_{1}}{τ} \} - \frac{{K}_{d} {K}_{0} {K}_{1}}{{τ}^{2}}}\end{matrix} \qquad ( 129 )$$

There is included a term of s³ in the denominator of the equation (129), which is higher in the order of s than the quadratic equation of s. However, by setting K_{d}K₀K₁<<τ², the equation may be approximated by

$$\begin{matrix}{H}_{e} ( s ) = \frac{( s + \frac{1}{τ} ) \{ {s}^{2} + ( \frac{{ω}_{0}}{Q} ) s + {ω}_{0}^{2} \}}{( s + \frac{1}{τ} ) \{ {s}^{2} + ( \frac{{ω}_{0}}{Q} ) s + {ω}_{0}^{2} + \frac{{K}_{d} {K}_{0} {K}_{1}}{τ} \} - \frac{{K}_{d} {K}_{0} {K}_{1}}{{τ}^{2}}} \\ \approx \frac{{s}^{2} + ( \frac{{ω}_{0}}{Q} ) s + {ω}_{0}^{2}}{{s}^{2} + ( \frac{{ω}_{0}}{Q} ) s + {ω}_{0}^{2} + \frac{{K}_{d} {K}_{0} {K}_{1}}{τ}} \\ = \frac{{s}^{2} + 2 s {ξω}_{n} + {ω}_{0}^{2}}{{s}^{2} + 2 s {ξω}_{n} + {ω}_{n}^{2}} \\ = 1 - H ( s )\end{matrix} \qquad ( 130 )$$

where ωₙ and ζ respectively denote the natural frequency represented by the equations (131):

$${ω}_{n} = \sqrt{\frac{{K}_{d} {K}_{0} {K}_{1} + {ω}_{0}}{τ}} \qquad ( 131 )$$

and the damping factor represented by the equation (132):

$$ξ = \frac{1}{2 {ω}_{n}} ( \frac{{ω}_{0}}{Q} ) \qquad ( 132 )$$

In case the loop filter 22 is an active RC filter, shown in FIG. 14B, the closed loop transfer function H(s) of the PLL circuit is given by

$$\begin{matrix}H ( s ) = \frac{\frac{{K}_{d} {K}_{0} {K}_{1} {K}_{a}}{τ} s}{\begin{matrix}{s}^{3} + \{ ( \frac{{ω}_{0}}{Q} ) + {ω}_{0}^{2} + \frac{1}{τ} \} {s}^{2} + \\ \{ \frac{1}{τ} ( \frac{{ω}_{0}}{Q} ) + \frac{{K}_{d} {K}_{0} {K}_{1} {K}_{a}}{τ} \} s + \frac{{ω}_{0}^{2}}{τ} + {ω}_{0}^{2}\end{matrix}} \\ = \frac{( s + \frac{1}{τ} ) \frac{{K}_{d} {K}_{0} {K}_{1} {K}_{a}}{τ} - \frac{{K}_{d} {K}_{0} {K}_{1} {K}_{a}}{{τ}^{2}}}{( s + \frac{1}{τ} ) \{ \begin{matrix}{s}^{2} + ( \frac{{ω}_{0}}{Q} ) s + \\ {ω}_{0}^{2} + \frac{{K}_{d} {K}_{0} {K}_{1} {K}_{a}}{τ}\end{matrix} \} - \frac{{K}_{d} {K}_{0} {K}_{1} {K}_{a}}{{τ}^{2}}}\end{matrix} \qquad ( 133 )$$

There is included a term of s³ in the denominator of the equation (133), which is higher in the order of s than the quadratic equation of s. However, by setting K_{d}K₀K₁Kₐ<<τ², the equation may be approximated by

$$\begin{matrix}H ( s ) = \frac{( s + \frac{1}{τ} ) \frac{{K}_{d} {K}_{0} {K}_{1} {K}_{a}}{τ} - \frac{{K}_{d} {K}_{0} {K}_{1} {K}_{a}}{{τ}^{2}}}{( s + \frac{1}{τ} ) \{ \begin{matrix}{s}^{2} + ( \frac{{ω}_{0}}{Q} ) s + \\ {ω}_{0}^{2} + \frac{{K}_{d} {K}_{0} {K}_{1} {K}_{a}}{τ}\end{matrix} \} - \frac{{K}_{d} {K}_{0} {K}_{1} {K}_{a}}{{τ}^{2}}} \\ \approx \frac{\frac{{K}_{d} {K}_{0} {K}_{1} {K}_{a}}{τ}}{{s}^{2} + ( \frac{{ω}_{0}}{Q} ) s + {ω}_{0}^{2} + \frac{{K}_{d} {K}_{0} {K}_{1} {K}_{a}}{τ}} \\ = \frac{{ω}_{n}^{2} - {ω}_{0}^{2}}{{s}^{2} + 2 s {ξω}_{n} + {ω}_{n}^{2}}\end{matrix} \qquad ( 134 )$$

In similar manner, the phase error transfer function Hₑ(s) is

$$\begin{matrix}{H}_{e} ( s ) = \frac{{s}^{3} + \{ ( \frac{{ω}_{0}}{Q} ) + {ω}_{0}^{2} + \frac{1}{τ} \} {s}^{2} + \frac{1}{τ} ( \frac{{ω}_{0}}{Q} ) s + \frac{{ω}_{0}^{2}}{τ} + {ω}_{0}^{2}}{\begin{matrix}{s}^{3} + \{ ( \frac{{ω}_{0}}{Q} ) + {ω}_{0}^{2} + \frac{1}{τ} \} {s}^{2} + \\ \{ \frac{1}{τ} ( \frac{{ω}_{0}}{Q} ) + \frac{{K}_{d} {K}_{0} {K}_{1} {K}_{a}}{τ} \} s + \frac{{ω}_{0}^{2}}{τ} + {ω}_{0}^{2}\end{matrix}} \\ = \frac{( s + \frac{1}{τ} ) \{ {s}^{2} + ( \frac{{ω}_{0}}{Q} ) s + {ω}_{0}^{2} \}}{( s + \frac{1}{τ} ) \{ {s}^{2} + ( \frac{{ω}_{0}}{Q} ) s + {ω}_{0}^{2} + \frac{{K}_{d} {K}_{0} {K}_{1} {K}_{a}}{τ} \} - \frac{{K}_{d} {K}_{0} {K}_{1} {K}_{a}}{{τ}^{2}}}\end{matrix} \qquad ( 135 )$$

There is included a term of s³ in the denominator of the equation (135), which is higher in the order of s than the quadratic equation of s. However, by setting K_{d}K₀K₁Kₐ<<τ², the equation may be approximated by

$$\begin{matrix}{H}_{e} ( s ) = \frac{( s + \frac{1}{τ} ) \{ {s}^{2} + ( \frac{{ω}_{0}}{Q} ) s + {ω}_{0}^{2} \}}{( s + \frac{1}{τ} ) \{ {s}^{2} + ( \frac{{ω}_{0}}{Q} ) s + {ω}_{0}^{2} + \frac{{K}_{d} {K}_{0} {K}_{1} {K}_{a}}{τ} \} - \frac{{K}_{d} {K}_{0} {K}_{1} {K}_{a}}{{τ}^{2}}} \\ \approx \frac{{s}^{2} + ( \frac{{ω}_{0}}{Q} ) s + {ω}_{0}^{2}}{{s}^{2} + ( \frac{{ω}_{0}}{Q} ) s + {ω}_{0}^{2} + \frac{{K}_{d} {K}_{0} {K}_{1} {K}_{a}}{τ}} \\ = \frac{{s}^{2} + 2 s {ξω}_{n} + {ω}_{0}^{2}}{{s}^{2} + 2 s {ξω}_{n} + {ω}_{n}^{2}} \\ = 1 - H ( s )\end{matrix} \qquad ( 136 )$$

where ωₙ and ζ respectively denote the natural frequency represented by the equations (137):

$${ω}_{n} = \sqrt{\frac{{K}_{d} {K}_{0} {K}_{a} {K}_{1} + {ω}_{0}}{τ}} \qquad ( 137 )$$

and the damping factor represented by the equation (138):

$$ξ = \frac{1}{2 {ω}_{n}} ( \frac{{ω}_{0}}{Q} ) \qquad ( 138 )$$

In case the loop filter 22 is the active inverting/integrating filter, shown in FIG. 14C, the closed-loop transfer function of the PLL circuit H(s) is

$$H ( s ) = \frac{\frac{{K}_{d} {K}_{0} {K}_{1}}{τ}}{{s}^{2} + ( \frac{{ω}_{0}}{Q} ) s + {ω}_{0}^{2} + \frac{{K}_{d} {K}_{0} {K}_{1}}{τ}} = \frac{{ω}_{n}^{2} - {ω}_{0}^{2}}{{s}^{2} + 2 s {ξω}_{n} + {ω}_{n}^{2}} \qquad ( 139 )$$

The phase error transfer function Hₑ(s) is

$$\begin{matrix}{H}_{e} ( s ) = \frac{{s}^{2} + ( \frac{{ω}_{0}}{Q} ) s + {ω}_{0}^{2}}{{s}^{2} + ( \frac{{ω}_{0}}{Q} ) s + {ω}_{0}^{2} + \frac{{K}_{d} {K}_{0} {K}_{1}}{τ}} \\ = \frac{{s}^{2} + 2 s {ξω}_{n} + {ω}_{0}^{2}}{{s}^{2} + 2 s {ξω}_{n} + {ω}_{n}^{2}} \\ = 1 - H ( s )\end{matrix} \qquad ( 140 )$$

where ωₙ and ζ respectively denote the natural frequency represented by the equations (141):

$${ω}_{n} = \sqrt{\frac{{K}_{d} {K}_{0} {K}_{1}}{τ} + {ω}_{0}^{2}} \qquad ( 141 )$$

and the damping factor represented by the equation (142):

$$ξ = \frac{1}{2 {ω}_{n}} ( \frac{{ω}_{0}}{Q} ) \qquad ( 142 )$$

It should be noticed that ωₙ and ζ are crucial parameters that govern the characteristics of the PLL circuit. If K_{d}K₀>>ωₙ or K_{d}KₐK₀>>ωₙ, this PLL system is said to be a high gain loop.

The most commonly used PLL has a high gain loop in order to improve tracking characteristic. Whether the PLL has a high gain loop or a low gain loop, ωₙ>>ω₀, while the time constant is of a large value, such that 1<<τ₁ and 1<<τ₁+τ₂. Hence the equations (128), (134) and (139) may be expressed by the following approximation:

$$H ( s ) \approx \frac{{ω}_{n}^{2}}{{s}^{2} + 2 s {ξω}_{n} + {ω}_{n}^{2}} \qquad ( 143 )$$

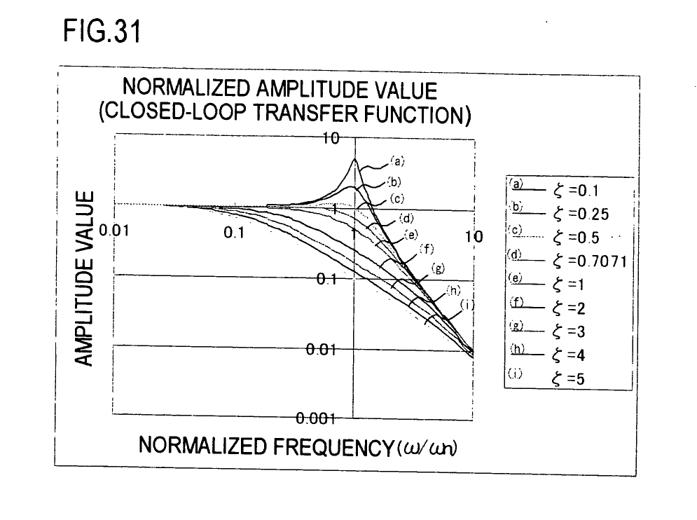

FIG. 31 shows amplitude characteristics of the closed-loop transfer function represented by the approximation (143), which is for the case of large values of the time constant of the equations (128), (134) and (139).

Also, whether the PLL has a high gain loop or a low gain loop, or whether a filter is a passive lag RC filter, an active RC filter or an active inverting/integrating filter, the time constant is of a large value, such that ω₀<<τ. Hence, the phase error transfer function Hₑ(s), shown by the equation (130), (136) or (140), may be represented by the following approximation:

$${H}_{e} ( s ) \approx \frac{{s}^{2} + 2 s {ξω}_{n}}{{s}^{2} + 2 s {ξω}_{n} + {ω}_{n}^{2}} \qquad ( 144 )$$

In the denominators of the phase error transfer functions Hₑ(s), shown by the equation (130), (136) or (140), or the approximation (143), there are contained terms of s other than the term s².

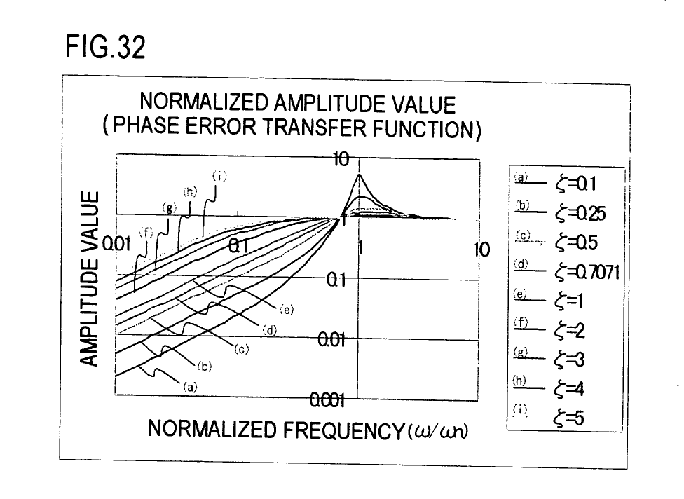

For reference sake, FIG. 32 shows amplitude characteristics of the approximation (144) which is to take the place of the phase error transfer function Hₑ(s). Even if the damping factor ζ is changed from 0.1 to 1, the amplitude values are all 1 for ω/ωₙ=1/√2. For ω/ωₙ>1/√2, the amplitude value becomes larger than 1, thus causing the overshooting.

The maximum value of the order of s in the denominator of the transfer function is 2, and hence the PLL is known as a second-order loop. Also, in a well-known manner, the amplitude characteristic |H(jω)| of the loop transfer function H(jω), shown by the approximation (143), has the characteristic of a second-order LPF, while the amplitude characteristic |Hₑ(jω)| of the phase error transfer function Hₑ(jω), shown by the approximation (144), has the characteristic of a second-order HPF.

The transfer function H(s) thus has a −3 dB cut-off frequency ω_{-3 dB}. It should be noticed that ω_{-3 dB} represents a closed loop band of the PLL circuit. If, in the high gain loop, the amplitude characteristic |Hₑ(jω)| is set so that

$$\vert H ( jω ) \vert = \frac{1}{\sqrt{2}}$$

and the transfer function is solved for ω, there may be obtained

$$\begin{matrix}{ω}_{- 3 dB} = {ω}_{n} \sqrt{1 - 2 {ξ}^{2} + \sqrt{1 + {( 2 {ξ}^{2} - 1 )}^{2}}} \\ = {ω}_{n} \sqrt{1 - 2 {ξ}^{2} + \sqrt{4 {ξ}^{4} - 4 {ξ}^{2} + 2}}\end{matrix} \qquad ( 145 )$$

Noteworthy is the fact that the closed loop transfer function, shown by the approximation (143), is the transfer function of the second-order LPF itself, while the phase error transfer function, defined by the approximation (144), is of the characteristic close to that of the second-order HPF. This relationship is the reverse of that of the case of the PLL circuit that makes use of the conventional VCO.

### NINTH EXAMPLE

In the seventh and eighth examples, the first-order LPF is used as the loop filter. However, since the PLL loop has the residual phase margin of 90°, the first-order LPF may be replaced by a cascaded connection of a first-order LPF and a lag-lead filter. In the case of the present example, the loop filter used is as shown in FIG. 21.

The transfer function for FIG. 21A is such that

$$\begin{matrix}{F}_{1} ( s ) = \frac{1}{1 + s {τ}_{1}} & ( 146 ) \\ {F}_{2} ( s ) = \frac{1 + s {τ}_{3}}{1 + s ( {τ}_{2} + {τ}_{3} )} \\ and & ( 147 ) \\ F ( s ) = {F}_{1} ( s ) \cdot {F}_{2} ( s ) = \frac{1}{1 + s {τ}_{1}} \frac{1 + s {τ}_{3}}{1 + s ( {τ}_{2} + {τ}_{3} )} & ( 148 )\end{matrix}$$

where τ₁=R₁C₁, τ₂=R₂C₂ and τ₃=R₃C₂.

For simplification, set τ₁=τ₃. Then,

$$F ( s ) = \frac{1}{1 + s ( {τ}_{2} + {τ}_{3} )} = \frac{1}{1 + s {τ}_{0}} \qquad ( 149 )$$

where τ₀=τ₁+τ₂.

The equation (149) represents a case equivalent to using an RC first-order LPF for the loop filter in each of the seventh and eighth examples and substituting τ₀ for τ in its transfer function F(s).

Similarly, the transfer function for FIG. 21(b) is such that

$$\begin{matrix}{F}_{1} ( s ) = \frac{1}{1 + s {τ}_{1}} & ( 150 ) \\ {F}_{2} ( s ) = {K}_{a} \frac{1 + s {τ}_{3}}{1 + s {τ}_{2}} \\ and & ( 151 ) \\ F ( s ) = {F}_{1} ( s ) \cdot {F}_{2} ( s ) = {K}_{o} \frac{1}{1 + s {τ}_{1}} \frac{1 + s {τ}_{3}}{1 + s {τ}_{2}} & ( 152 )\end{matrix}$$

where τ₁=R₁C₁, τ₂=R₂C₂, τ₃=R₃C₂ and Kₐ=C₂/C₃.

For simplification, set τ₁=τ₃. Then,

$$F ( s ) = \frac{1}{1 + s {τ}_{2}} = \frac{1}{1 + s {τ}_{0}} \qquad ( 153 )$$

where τ0=τ2.

The equation (153) represents a case equivalent to using an RC first-order LPF for the loop filter in each of the seventh and eighth examples and substituting τ₀ for τ in its transfer function F(s)

Likewise, the transfer function for FIG. 21C is such that

$$\begin{matrix}{F}_{1} ( s ) = \frac{1}{1 + s {τ}_{1}} & ( 154 ) \\ {F}_{2} ( s ) = \frac{1 + s {τ}_{3}}{s {τ}_{2}} \\ and & ( 155 ) \\ F ( s ) = {F}_{1} ( s ) \cdot {F}_{2} ( s ) = {K}_{a} \frac{1}{1 + s {τ}_{1}} \frac{1 + s {τ}_{3}}{s {τ}_{2}} & ( 156 )\end{matrix}$$

where τ₁=R₁C₁, τ₂=R₂C₂ and τ₃=R₃C₂.

For simplification, set τ₁=τ₃. Then,

$$F ( s ) = \frac{1}{s {τ}_{2}} = \frac{1}{s {τ}_{0}} \qquad ( 157 )$$

where τ₀=τ₂.

The equation (157) represents a case equivalent to using an RC first-order LPF for the loop filter in each of the seventh and eighth examples and substituting τ₀ for τ in its transfer function F(s).

It is thus possible to use a cascaded connection of an RC first-order LPF and a lag-lead filter as a loop filter in each of the seventh and eighth examples.

### TENTH EXAMPLE

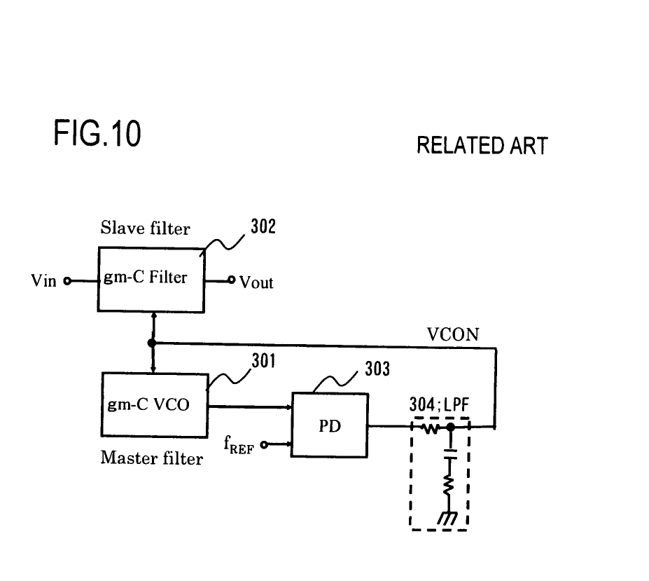

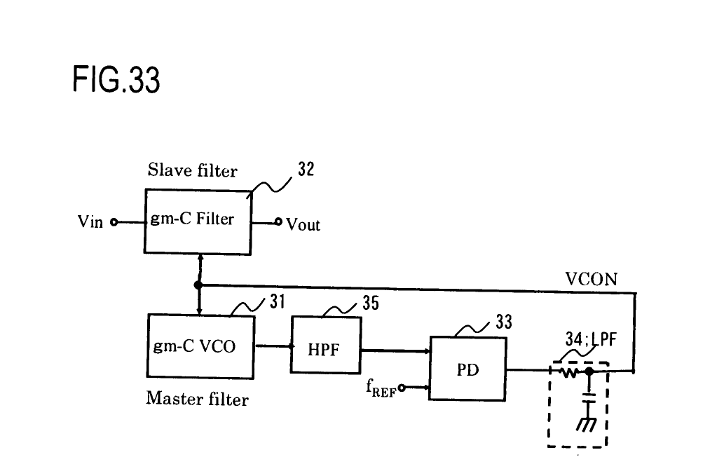

An example of a frequency setting circuit, making use of the PLL circuit of the present invention, is now described. FIG. 33 shows an example of the configuration of a first example of a frequency setting circuit for a gm-C filter in which a PLL circuit that makes use of a VCO of the present invention is used as a control circuit. In FIG. 33, an HPF 35 is inserted between a VCO circuit 31, formed by gm and C, and a phase detector (PD) 33. The present example corresponds to the configuration of FIG. 10 in which an HPF is inserted between the gm-C VCO circuit 301 and the PD 303.

### ELEVENTH EXAMPLE

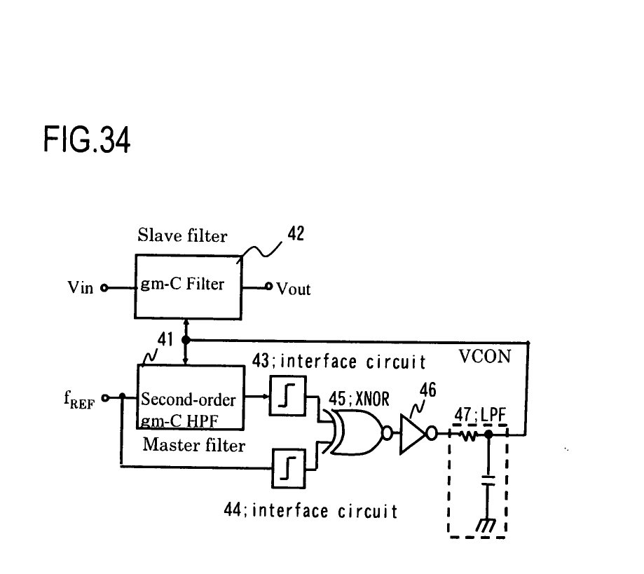

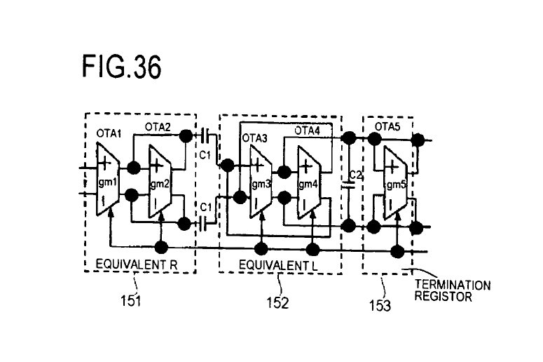

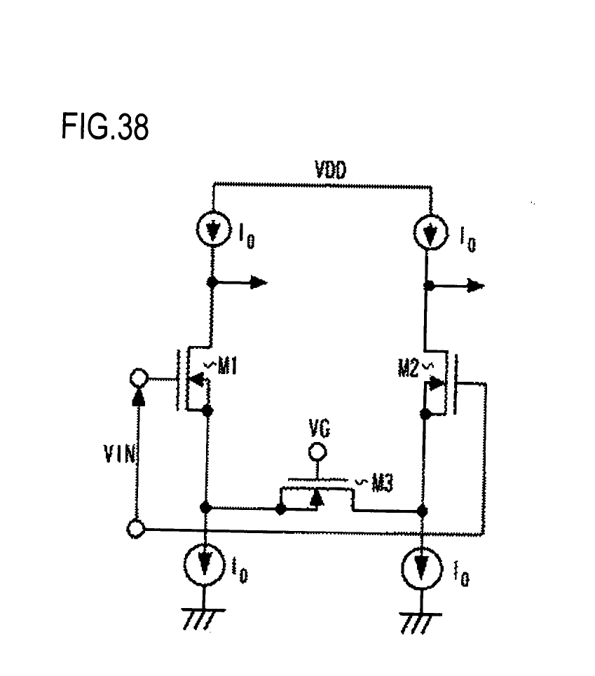

FIG. 34 shows an example of the configuration of a first example of a frequency setting circuit for a gm-C filter in which a PLL circuit that makes use of a VCO of the present invention is used as a control circuit. In FIG. 34, a second-order HPF 41 formed by gm-C (second-order gm-C HPF 41) is used as a VCF circuit. The phase difference between the reference frequency and the VCF output is 90°. FIG. 36 shows an example of a differential second-order HPF 41 (second-order gm-C HPF) including a plurality of OTAs and capacitors (see Patent Document 2). Referring to FIG. 36, the second-order gm-C HPF includes an equivalent R 151 (made up of two OTAs, that is, OTA1 and OTA2), an equivalent L151 (made up of two OTAs, that is, OTA3 and OTA4), a capacitor C2, and a termination resistor 153, made up of an OTA, that is, OTA5. Each OTA is constituted as shown for example in FIG. 38. In the example of FIG. 38, there is provided a transistor M3, operating in a linear region, in place of the degeneration resistance of a differential pair M1 and M2. The degeneration resistance is equivalently varied by varying the gate voltage of the transistor M3 to vary the transconductance (mutual conductance) gm of the OTA. It is also possible to construct OTA1 to OTA5 of FIG. 36 as shown in FIG. 38 and to supply the control voltage VCON (d.c. voltage) as the gate voltage of the transistor M3 of the OTA.

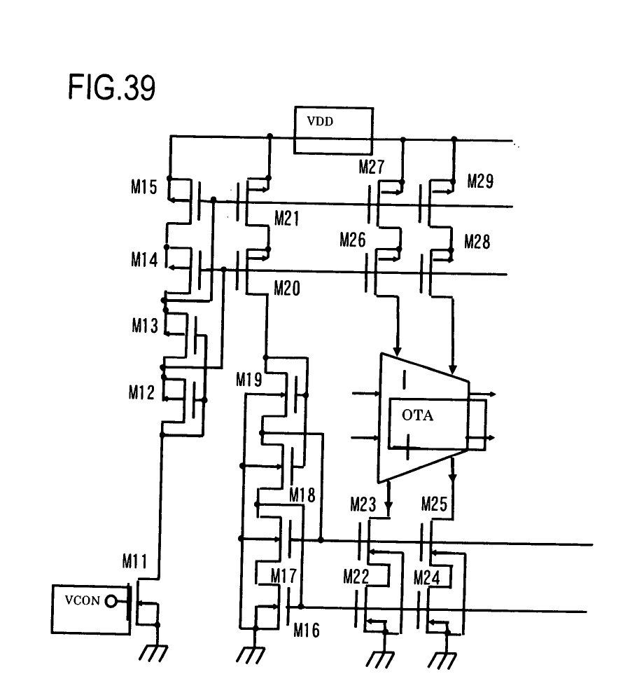

Alternatively, the control voltage VCON may be converted by a voltage-to-current (V-I) converter, not shown, into a current (output current of the V-I converter) to control the driving current for the OTA based on the output current of the V-I converter such as to vary the OTA's transconductance (gm). FIG. 39 shows an example of the configuration of converting the control voltage VCON into the current by the V-I converter to vary the OTA's driving current. Referring to FIG. 39, there are provided an n-channel MOS transistor M11, having a source grounded and having a gate supplied with the control voltage, p-channel MOS transistors M12 to M15, cascode-connected between the drain of the transistor M11 and the power supply VDD, nMOS transistors M16 to M19 and p-MOS transistors M20, M21 connected between the ground and the power supply. Also are provided, as current sources corresponding to the current sources 10 of the OTA of FIG. 38, n-channel MOS transistors M22 and M23, n-channel MOS transistors M24 and M25, p-channel MOS transistors M26 and M27 and p-channel MOS transistors M28 and M29. The transistors M26 and M27 and the transistors M28 and M29 form the output side of a first cascode current mirror circuit. The transistors M22 and M23 and the transistors M24 and M25 form the output side of a second cascode current mirror circuit that receives the output current of the first cascode current mirror circuit (output current of the transistor M20). The current corresponding to the drain current of the transistor M11, equivalent to the control voltage VCON, is supplied to the OTA via the first and second cascode current mirror circuits.

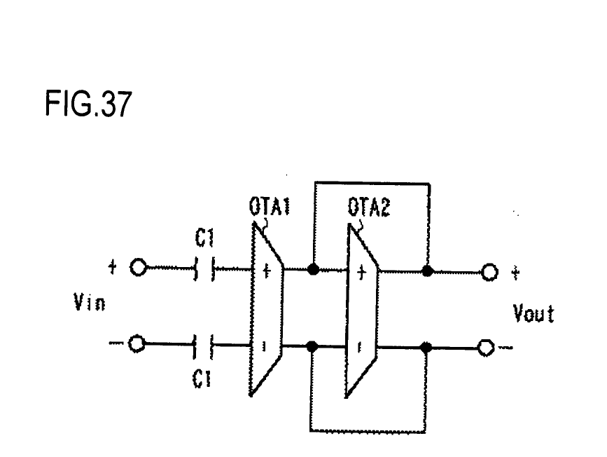

FIG. 35 shows a configuration of a second example of a frequency setting circuit for a gm-C filter in which a PLL circuit employing the VCF according to the present invention is used as a control circuit. Referring to FIG. 35, a first-order gm-C HPF 51 is used as a VCF circuit, and an operational amplifier (OP amp) 58, having one-fourth of the power supply voltage VDD as a reference voltage, is provided in rear of an RC first-order LPF 57. The phase difference between the reference frequency and the output of the first-order gm-C HPF 51 is thus equal to 45°. FIG. 37 shows an example of a differential first-order HPF 51 (first-order gm-C HPF) made up of a plurality of OTAs and a capacitor (see Patent Document 1). The OTAs OTA1 and OTA2 may be configured as shown in FIG. 38, for instance. The control voltage VCON (d.c. voltage), output from the operational amplifier (OP amp) 58, may also be delivered to the gate terminal of the transistor M3 of the OTA. Alternatively, the control voltage VCON, output from the operational amplifier (OP amp) 58, may be converted into a current, as shown in FIG. 39, to vary the OTA's driving current such as to vary its transconductance (gm).

As an instance for practical application, the PLL of the present invention may be used not only for generating the local (LO) frequency for a routine radio system, or for generating the clock, but also in a control circuit configured for tuning the gm-C filter formed on an integrated circuit.

The disclosures of the aforementioned Patent Documents and the Non-Patent Documents are incorporated herein by reference. Within the framework of the entire disclosure of the present invention, inclusive of claims, the examples or preferred examples may be changed or adapted, based on the basic technical concept of the invention. That is, those skilled in the art can change or modify the examples or preferred examples without departing from the scope and the spirit of the invention.

It should be noted that other objects, features and aspects of the present invention will become apparent in the entire disclosure and that modifications may be done without departing the gist and scope of the present invention as disclosed herein and claimed as appended herewith. Also it should be noted that any combination of the disclosed and/or claimed elements, matters and/or items may fall under the modifications aforementioned.

What is claimed is:

1. A PLL circuit comprising:
a frequency oscillator that has an oscillation frequency controlled by an electrical signal;
a high pass filter that receives an output signal of said frequency oscillator;
a phase detector that receives an output of said high pass filter and a reference frequency at first and second input terminals thereof, respectively to detect a phase difference between signals at the first and second input terminals; and
a loop filter that receives an output signal of said phase detector; a DC component output from said loop filter being supplied as said electrical signal to said frequency oscillator.

2. A PLL circuit comprising:
a frequency oscillator that has an oscillation frequency controlled by an electrical signal;
a delay circuit that delays an inverted signal of an output signal of said frequency oscillator:
a phase detector that receives an output of said delay circuit and a reference frequency at first and second input terminals thereof, respectively to detect a phase difference between signals at the first and second input terminals; and
a loop filter that receives an output signal of said phase detector; a DC component output from said loop filter being supplied as said electrical signal to said frequency oscillator.

3. The PLL circuit according to claim 1, further comprising:
a frequency divider connected between said frequency oscillator and said phase detector.

4. The PLL circuit according to claim 1, wherein said frequency oscillator includes a plurality of operational transconductance amplifiers and a capacitor.

5. A PLL circuit comprising
a phase locked loop including:
a phase shifter that includes a plurality of operational transconductance amplifiers and a capacitor, said phase shifter receiving an AC signal of a preset frequency;
a phase detector that receives an input signal to said phase shifter and an output signal from said phase shifter and outputs a signal corresponding to the phase difference between said signals; and
a loop filter that receives an output of said phase detector; wherein
said phase locked loop varies the transconductance (gm) of at least one of said operational transconductance amplifiers that make up said phase shifter, with a DC component from said loop filter as a control signal, to exercise control to render the phase difference at said phase shifter constant; and wherein
the phase advances in said phase shifter.

6. A PLL circuit comprising
a phase locked loop including
a phase shifter that includes a plurality of operational transconductance amplifiers and a capacitor, said phase shifter receiving an AC signal of a preset frequency;
a phase detector that receives an input signal to said phase shifter and an output signal from said phase shifter and outputs a signal corresponding to the phase difference between said signals; and
a loop filter that receives an output of said phase detector; wherein
said phase locked loop varies the transconductance (gm) of at least one of said operational transconductance amplifiers that make up said phase shifter, via an amplifier that amplifies a DC voltage output from said loop filter, with an output voltage of said amplifier as a control signal, to exercise control to render the phase difference at said phase shifter constant; and wherein
the phase advances in said phase shifter.

7. A PLL circuit comprising
a phase locked loop including:
a phase shifter that includes a plurality of operational transconductance amplifiers and a capacitor, said phase shifter receiving an AC signal of a preset frequency;
a phase detector that receives an input signal to said phase shifter and an output signal from said phase shifter and outputs a signal corresponding to the phase difference between said signals; and
a loop filter that receives an output signal of said phase detector; wherein
a DC voltage from said loop filter is converted to a current by a voltage-to-current converter; and
said phase locked loop varies the transconductance (gm) of at least one of said operational transconductance amplifiers that make up said phase shifter, with an output voltage of said voltage-to-current converter as a control signal; and wherein
the phase advances in said phase shifter.

8. The PLL circuit according to claim 7, wherein the voltage is converted to the current by said voltage-to-current converter via an amplifier that amplifies the DC voltage of the output signal of said phase detector.

9. The PLL circuit according to claim 4, wherein said phase shifter includes a second-order high pass filter.

10. The PLL circuit according to claim 5, wherein said phase shifter includes a first-order high pass filter.

11. The PLL circuit according to claim 1, wherein said loop filter includes an RC first-order low pass filter.

12. The PLL circuit according to claim 5, wherein said loop filter includes
a second-order low pass filter which includes a first-order low pass filter and a lag-lead filter which are cascade-connected.

13. A PLL circuit comprising
a phase locked loop including:
a phase shifter comprising a high pass filter provided with a plurality of operational transconductance amplifiers and a capacitor; said phase shifter receiving an AC signal of a preset frequency as an input signal and outputting a control signal corresponding to said input signal phase-shifted by a preset amount; with the phase shift amount being controlled by said control signal;
a phase detector receiving an input signal to said phase shifter and an output signal from said phase shifter and outputting a signal corresponding to the phase difference between said signals;
a loop filter receiving an output of said phase detector to output a DC voltage; and
a differential amplifier differentially amplifying an output voltage of said loop filter and an input reference voltage;
an output voltage of said differential amplifier being fed back, as a control signal, to said phase shifter;
said control signal operating for varying the transconductance (gm) of at least one of the operational transconductance amplifiers making up said phase shifter to exercise control to render constant the phase difference in said phase shifter;
wherein said reference voltage is not more than one-half of the power supply voltage.

14. A frequency setting circuit comprising a gm-C filter including a plurality of operational transconductance amplifiers controlled in common by said control signal from said PLL circuit as set forth in claim 1.
